(19) United States
(12) Patent Application Publication
(10) Pub. No.: US 2011/0126883 A1
(43) Pub. Date: Jun. 2, 2011

(54) METHOD AND APPARATUS FOR EXTRACTING ENERGY FROM INSOLATION

(75) Inventor: Arnold J. Goldman, Jerusalem (IL)

(73) Assignee: BRIGHTSOURCE INDUSTRIES (ISRAEL) LTD., Jerusalem (IL)

(21) Appl. No.: 12/954,863

(22) Filed: Nov. 27, 2010

Related U.S. Application Data
(60) Provisional application No. 61/264,709, filed on Nov. 27, 2009.

(51) Int. Cl. H01L 31/052

(52) U.S. Cl. 136/246

(57) ABSTRACT

Light management systems and related methods disclosed herein are able to re-direct solar insolation. In some embodiments, a system for harvesting insolation may include a solar target, such as one or more photovoltaic assemblies and/or bioreactor targets. In some embodiments, a substantially uniform light distribution is provided within and/or on the targets.

### CROSS-REFERENCE TO RELATED APPLICATIONS

The present application claims the benefit of U.S. Provisional Application No. 61/264,709, filed Nov. 27, 2009, which is hereby incorporated by reference herein in its entirety.

### FIELD

The present disclosure relates generally to solar energy systems, and, more particularly, to methods and apparatus for extracting energy from insolation.

### SUMMARY

Embodiments of the present disclosure relate to apparatus and methods for extracting energy from insolation. Some embodiments of the present invention relate to techniques for producing a biofuel (including but not limited to butanol) from insolation. Some embodiments of the present invention relate to techniques for generating electricity—for example, from a solar PVC.

In embodiments, a system for harvesting solar energy can include an elongated upright target and first and second reflection assemblies. The elongated upright target can include first and second vertical surfaces that face away from each other. The first and second reflection assemblies can be located on respective sides of the elongated upright target, such that the first reflection assembly is located on the first side of the elongated upright target and the second reflection assembly is located on the second side of the elongated upright target. Each reflection assembly can include a respective field of heliostats located on the respective side of the target and a respective, at least partially reflecting element located above the heliostat field. In embodiments, a system for harvesting solar energy can include a target and first and second reflecting assemblies. The target can have first and second surfaces. The first surface may be non-coplanar with respect to said second surface. The first reflecting assembly can be arranged to reflect incident solar radiation at the first target surface while the second reflecting assembly can be arranged to reflect incident solar radiation at said second target surface. Each reflecting assembly can include at least one heliostat and at least one wavelength selective reflector. The at least one heliostat can be configured to reflect solar radiation onto the at least one wavelength selective reflector and thereby onto the respective target surface.

Objects and advantages of embodiments of the present disclosure will become apparent from the following description when considered in conjunction with the accompanying drawings.

### BRIEF DESCRIPTION OF THE DRAWINGS

Embodiments will hereinafter be described with reference to the accompanying drawings, which have not necessarily been drawn to scale. Where applicable, some features may not be illustrated to assist in the illustration and description of underlying features. Throughout the figures, like reference numerals denote like elements.

FIG. 1 is a schematic diagram showing an aerial view of a system for extracting energy from insolation, according to one or more embodiments of the disclosed subject matter.

FIG. 2A is a schematic diagram showing an isometric view of an elongated target, according to one or more embodiments of the disclosed subject matter.

FIG. 2B is a schematic diagram showing an isometric view of a bioreactor as an elongated target, according to one or more embodiments of the disclosed subject matter.

FIG. 3A is a schematic diagram illustrating a system for reflecting sunlight simultaneously onto left and right surfaces of a target, for example a bioreactor, according to one or more embodiments of the disclosed subject matter.

FIG. 3B is a schematic diagram illustrating a system for reflecting sunlight with an elevated reflector that splits light beams according to wavelength, according to one or more embodiments of the disclosed subject matter.

FIG. 3C is a schematic diagram illustrating a system for reflecting sunlight including photovoltaic cells, according to one or more embodiments of the disclosed subject matter.

FIGS. 3D-3E are schematic diagrams illustrating systems with photovoltaic cells included in the elongated target, according to one or more embodiments of the disclosed subject matter.

FIGS. 4A-4B are schematic diagrams showing a side view of systems for reflecting sunlight onto left and right surfaces of a target, according to one or more embodiments of the disclosed subject matter.

FIG. 5 is a schematic diagram of a heliostat, according to one or more embodiments of the disclosed subject matter.

FIG. 6 is schematic diagram showing an isometric view of a single reactor column, according to one or more embodiments of the disclosed subject matter.

FIG. 7 is a schematic diagram showing an isometric view of a module, according to one or more embodiments of the disclosed subject matter.

FIG. 8 shows a cross-sectional view of a module in operation, according to one or more embodiments of the disclosed subject matter.

FIG. 9 shows a cross-sectional view of a slanted growth plate, according to one or more embodiments of the disclosed subject matter.

FIG. 10 is a close-up view of a module showing feed and exit pipes, according to one or more embodiments of the disclosed subject matter.

FIG. 11 is a schematic diagram showing a cross-sectional view of modules connected in parallel, according to one or more embodiments of the disclosed subject matter.

FIG. 12 is a schematic diagram showing a cross-sectional view of modules connected in series, according to one or more embodiments of the disclosed subject matter.

FIG. 13 is a schematic diagram showing a cross-sectional view of a bioreactor with a Fresnel lens, according to one or more embodiments of the disclosed subject matter.

FIGS. 14A-14B show timelines for operation of a nursery bioreactor, according to one or more embodiments of the disclosed subject matter.

FIG. 15 is a schematic diagram showing an aerial view of a system as a portion of a biofuel plant, according to one or more embodiments of the disclosed subject matter.

FIG. 16 is a graph of time versus gas bubble radius to reach 95% saturation with butanol in spherical gas bubbles produced in an aqueous butanol solution at 35° C.

FIG. 17 is a graph showing the stripping rate versus concentration in a one-liter butanol solution at 35° C.

FIG. 18 shows a partial isometric view of a C-300 stripping unit, according to one or more embodiments of the disclosed subject matter.

FIG. 19 shows an air pipe with diffusers, according to one or more embodiments of the disclosed subject matter.

FIGS. 20-21 show partial isometric views of a C-300 stripping unit, according to one or more embodiments of the disclosed subject matter.

FIG. 22 is a schematic diagram illustrating bio-solution flow patterns in a bioreactor, according to one or more embodiments of the disclosed subject matter.

FIG. 23 is a table of mass balance for one cycle of operation, according to one or more embodiments of the disclosed subject matter.

FIG. 24 is a table of pump power data for the system, according to one or more embodiments of the disclosed subject matter.

### DETAILED DESCRIPTION

The following publications are hereby incorporated by reference in their entirety as if fully set forth herein: U.S. Publication No. 2009/0197322, published Aug. 6, 2009, entitled “Solar Plant Employing Cultivation of Organisms”; U.S. Publication No. 2009/0155864, published Jun. 18, 2009, entitled “Systems, Methods, and Devices for Employing Solar Energy to Produce Biofuels”; U.S. Publication No. 2008/0293132, published Nov. 27, 2008, entitled “High Density Bioreactor System, Devices, and Methods”; U.S. Publication No. 2008/0011290, published Jan. 17, 2008, entitled “High Temperature Solar Receiver”; U.S. Publication No. 2008/0000436, published Jan. 3, 2008, entitled “Low Emission Energy Source”; U.S. Publication No. 2007/0221208, filed, entitled; U.S. Publication No. 2007/0157614, published Sep. 27, 2007, entitled “High-Temperature Pipeline”; U.S. Publication No. 2007/0012041, published Jan. 18, 2007, entitled “Hybrid Generation with Alternative Fuel Sources”; and U.S. Publication No. 20050279095, published Dec. 22, 2005, entitled “Hybrid Generation with Alternative Fuel Sources.” Some embodiments of the disclosed subject matter may include any feature or combination of features disclosed in the incorporated documents.

Embodiments of the disclosed subject matter relate to apparatus and methods for extracting energy from insolation. Some embodiments of the disclosed subject matter relate to techniques for producing biofuel (including but not limited to butanol) from insolation. Some embodiments of the disclosed subject matter relate to techniques for generating electricity—for example, from a solar photovoltaic cell (PVC).

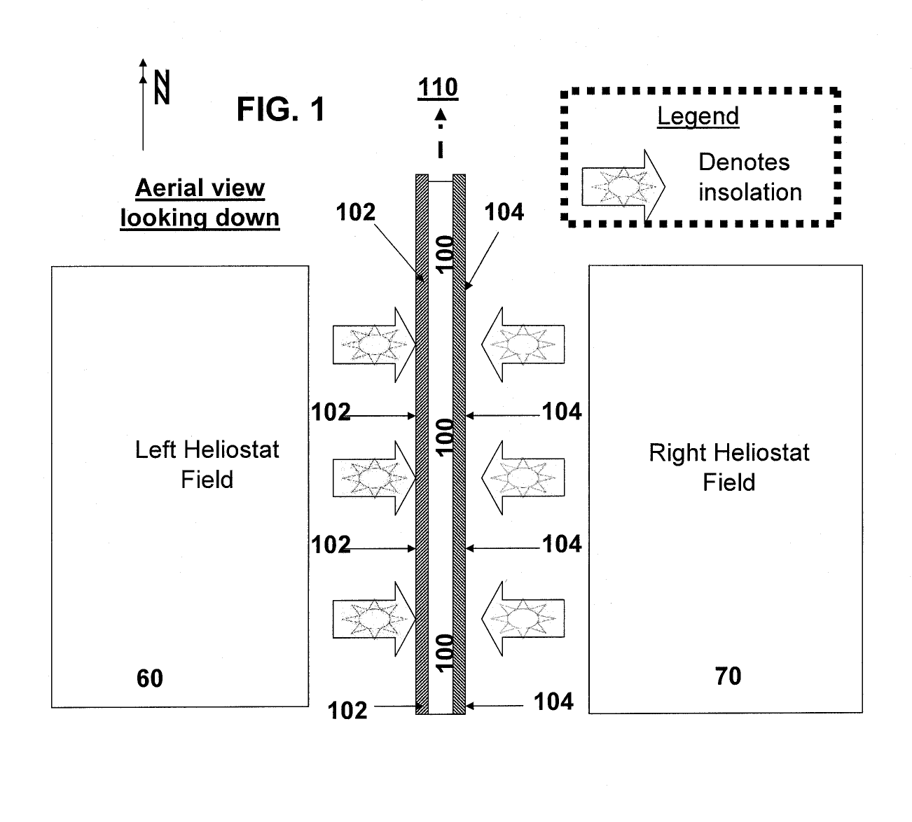

FIG. 1 is an aerial view of a system for extracting energy from insolation including (i) a left heliostat field 60; (ii) an elongated target 100; and (iii) a right heliostat field. Heliostats in both the left and right heliostat field reflect sunlight directly or indirectly to the elongated target 100.

In the non-limiting example of FIG. 1, elongated target 100 is orientated in a north-south orientation. Thus, the elongate axis 110 of elongated target 100 is oriented in the N—S orientation. Although the elongated target is depicted as a straight line, it is appreciated that in some embodiments, elongated target is not exactly straight, and may even includes curves or other deviations from a straight line.

Elongated target 100 includes two surfaces: a first “left” surface 102 facing left heliostat field 60 and a second “right” surface 104 facing right heliostat field 70. Solar beams derived from sunlight incident on and reflect by heliostats of the left 60 heliostat field are projected upon the left surface 102; simultaneously, solar beams derived from sunlight incident on and reflected by heliostats of the right 70 heliostat field are projected upon the left surface 104.

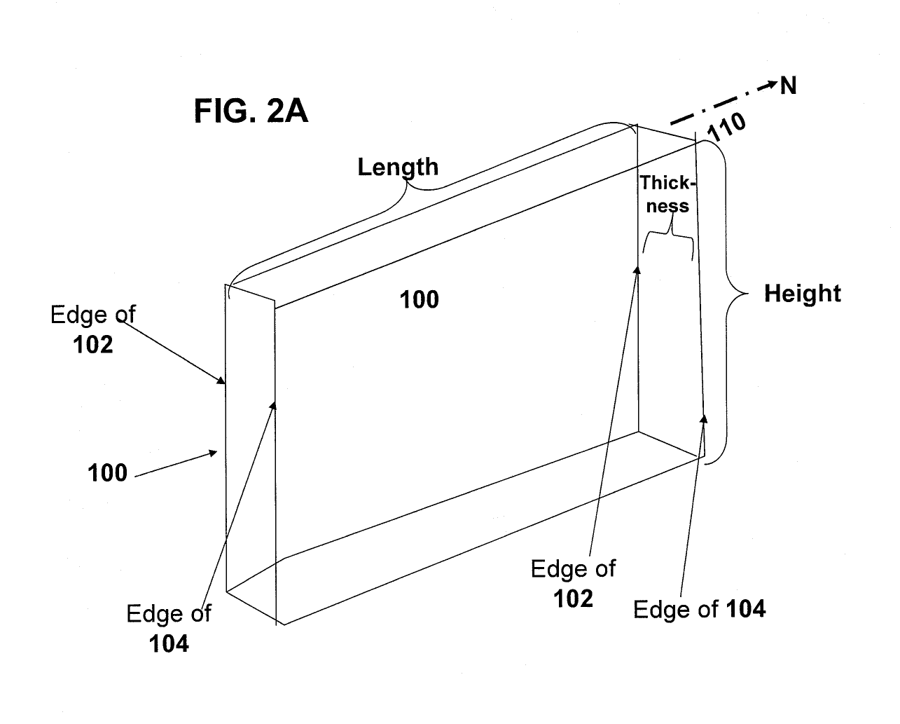

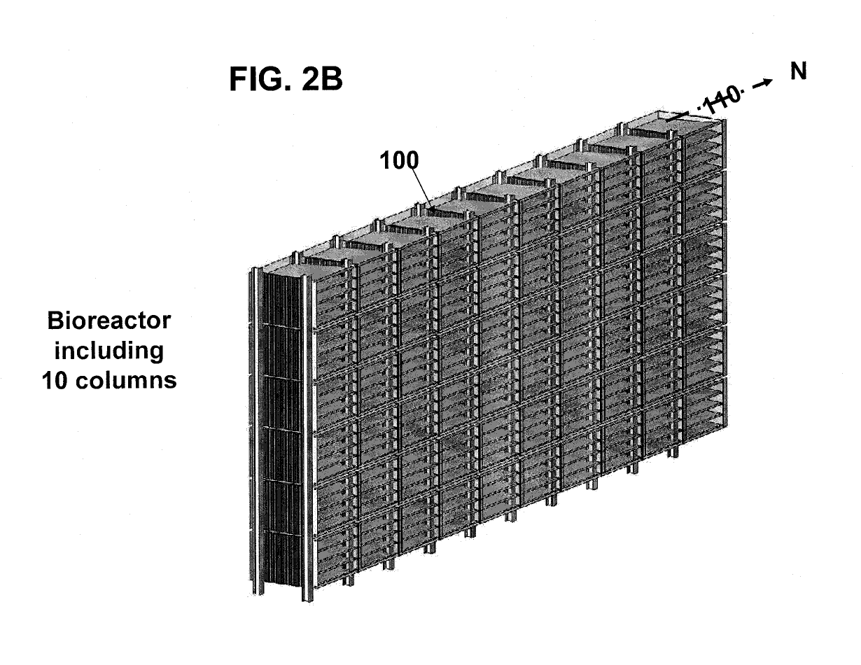

As illustrated in FIG. 2A, in some embodiments, the elongated target is an upright target and/or a thin target. Thus, in some embodiments, a ratio between a height of the target 100 and a thickness of the target is at least 3 or 5 or 10 or 20. In some embodiments, a ratio between a length of the target 100 and a height of the target is at least 5 or 10 or 50 or 100 or 500. In some embodiments, left vertical surface 102 and/or right vertical surface 104 are substantially planar.

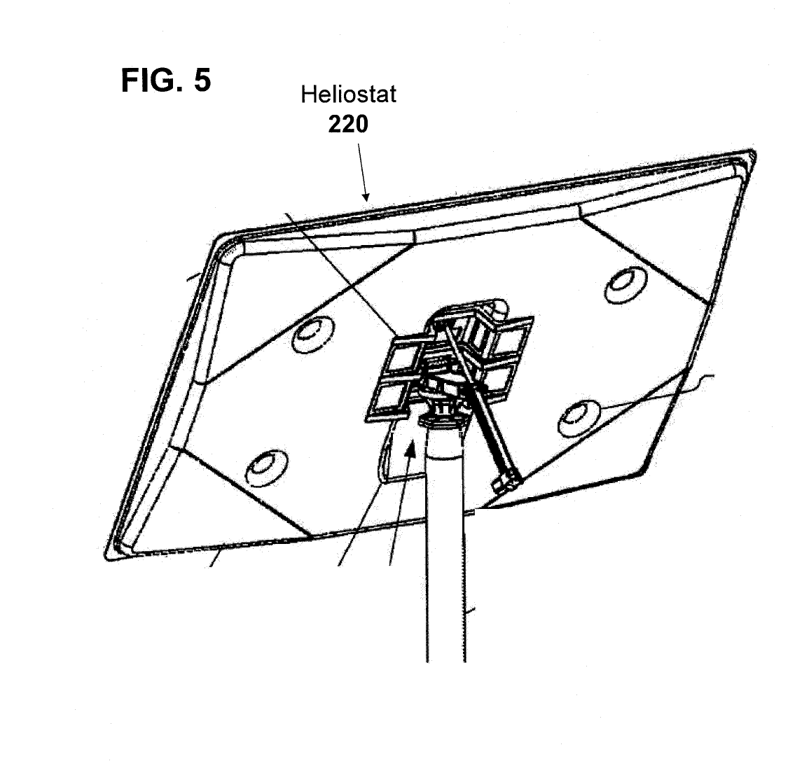

In one non-example (FIG. 2B), the target is a bioreactor, for example, a bioreactor including a plurality of columns (one exemplary column is illustrated in FIG. 5). Alternatively or additionally, photovoltaic cells are deployed on the left surface 102 and/or the right 104 surface.

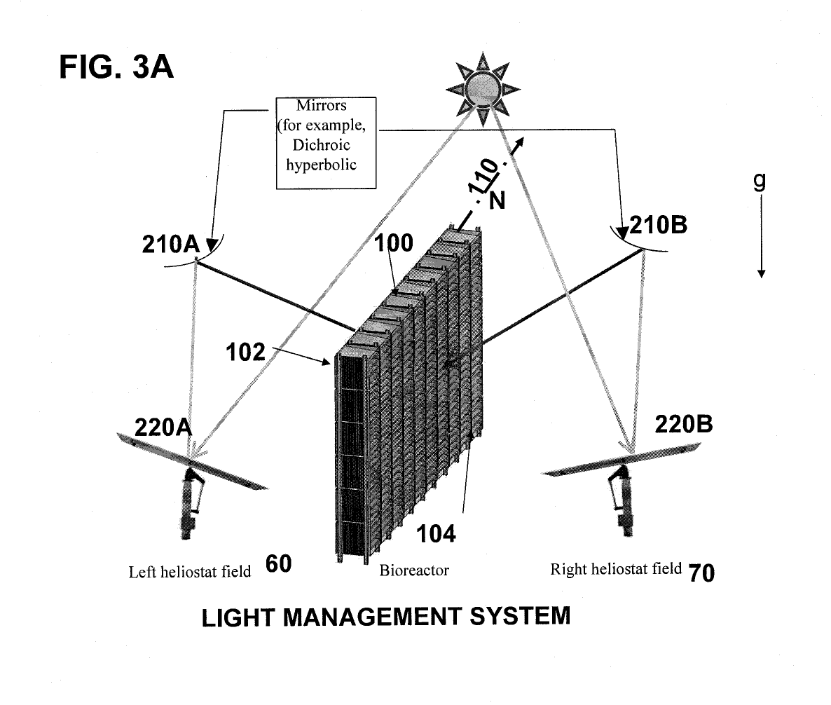

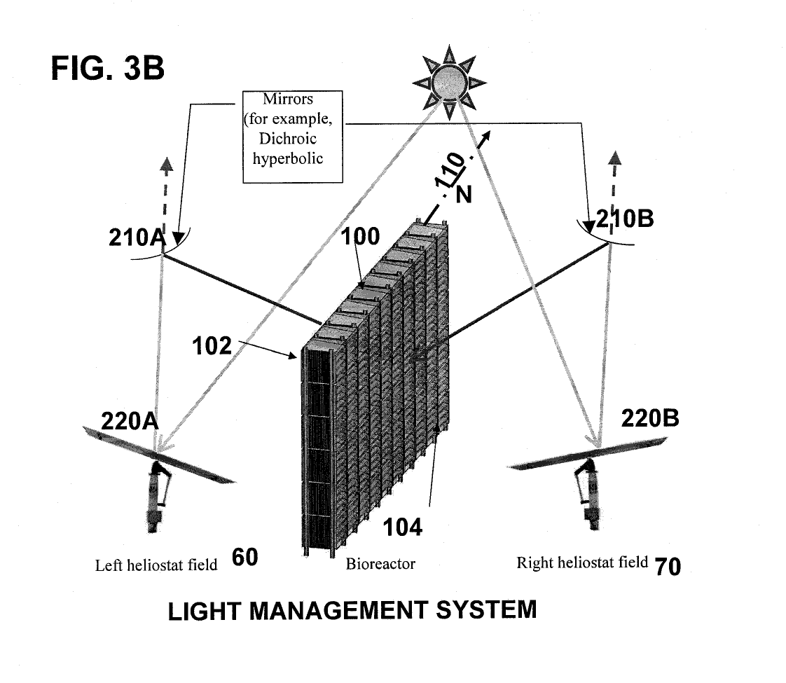

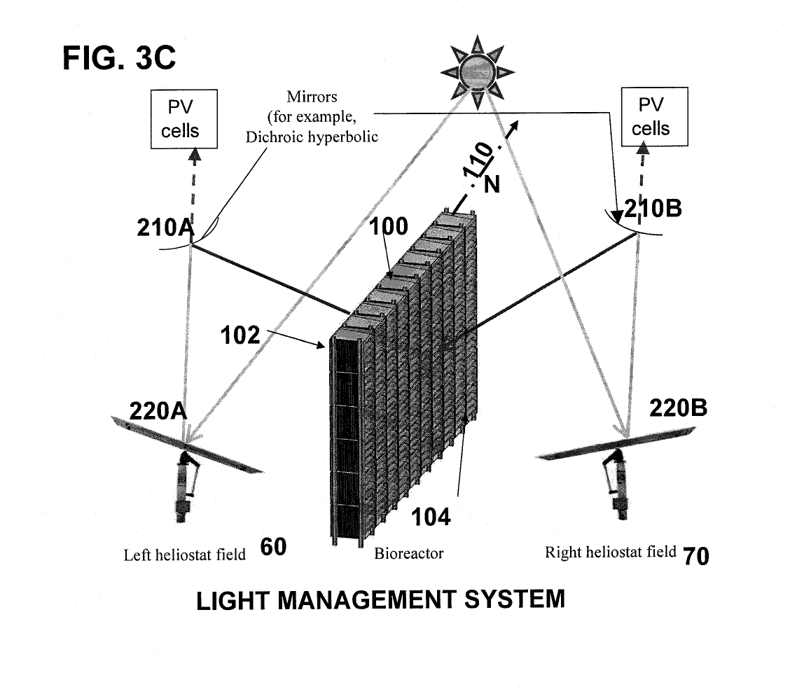

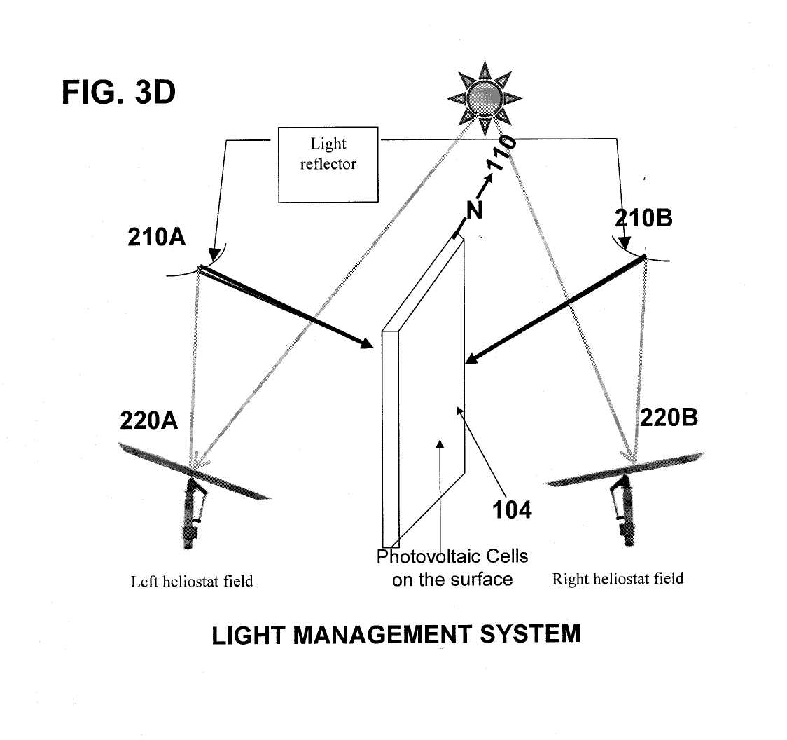

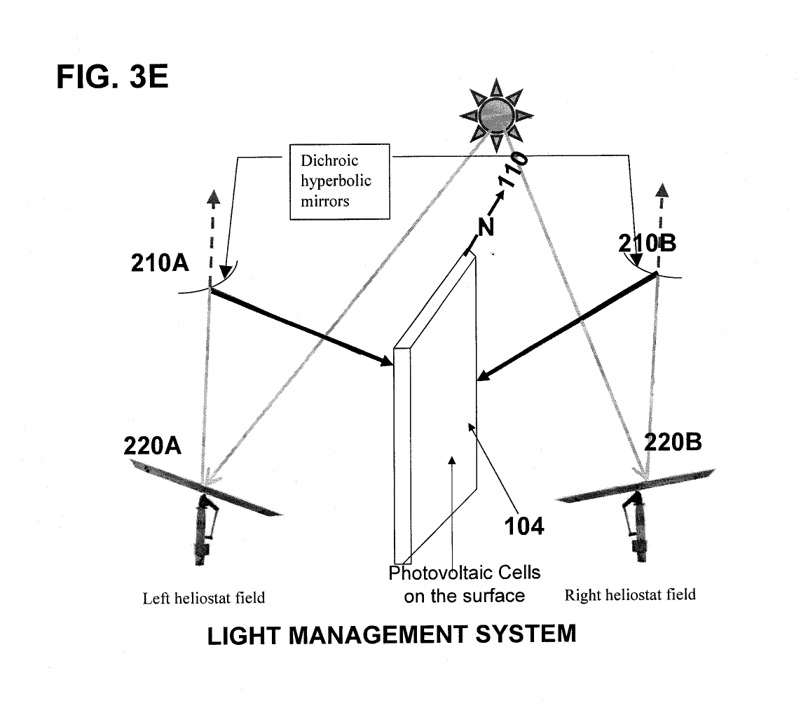

FIG. 3A illustrates an exemplary system for reflecting sunlight simultaneously onto both the left 102 and right 104 surfaces of target 100. In the example of FIG. 3A, a heliostat 220A (for example, at ground level or substantially at ground level) in the left heliostat field 60 reflects sunlight in an upwards at an elevated reflector 210A. The elevated reflector 210A in turn reflects light to the left surface 102 of target 100. In the example of FIG. 3A, a heliostat 220B (for example, at ground level or substantially at ground level) in the right heliostat field 60 reflects sunlight in an upwards at an elevated reflector 220A. The elevated reflector 220B in turn reflects light to the left surface 102 of target 100.

In one non-limiting example, elevated reflector is mounted to a tower at a height of at least 5 or 10 or 20 or 25 or 50 meters. In another example, elevated reflector is mounted to a helium balloon.

In the example of FIG. 3B, the reflecting element 210 is configured to split the beam received from the heliostats according to wavelength—thus, some wavelengths are reflected down to the target 100 while other wavelengths may pass through. In one non-limiting example, the reflector is a dichroic and/or hyperbolic mirror.

In one use case, (i) blue light of the upward light beam from the heliostat may pass through the mirror 210 and be incident upon one or more photovoltaic (PV) cells (see FIG. 3C) for generating electricity while (ii) red light of the upward light beam from the heliostat may be reflected by the reflector/mirror 210 down to the target. This red light may be useful for a photosynthetic process within target 100—for example, a photosynthetic process for generating one or more biofuels.

For example, a photosynthetic organism (for example, a photosynthetic microbe and/or an algae and/or a cyanobacteria) may be present within target 100. Insolation incident upon the left 102 and right 104 surfaces may be useful for facilitating growth of the photosynthetic organism and/or biofuel production. Exemplary biofuels include but are not limited to ethanol, isobutanol, isoprene (C₅H₈), isopenenol (C₅H₉OH), lauric acid (precursor of dodecanol, a 12-carbon alcohol) and octanol (8-carbon alcohol).

FIGS. 3D-3E relate to examples where PV cells are present on or within target 100 and receive insolation from reflectors 210A-210B.

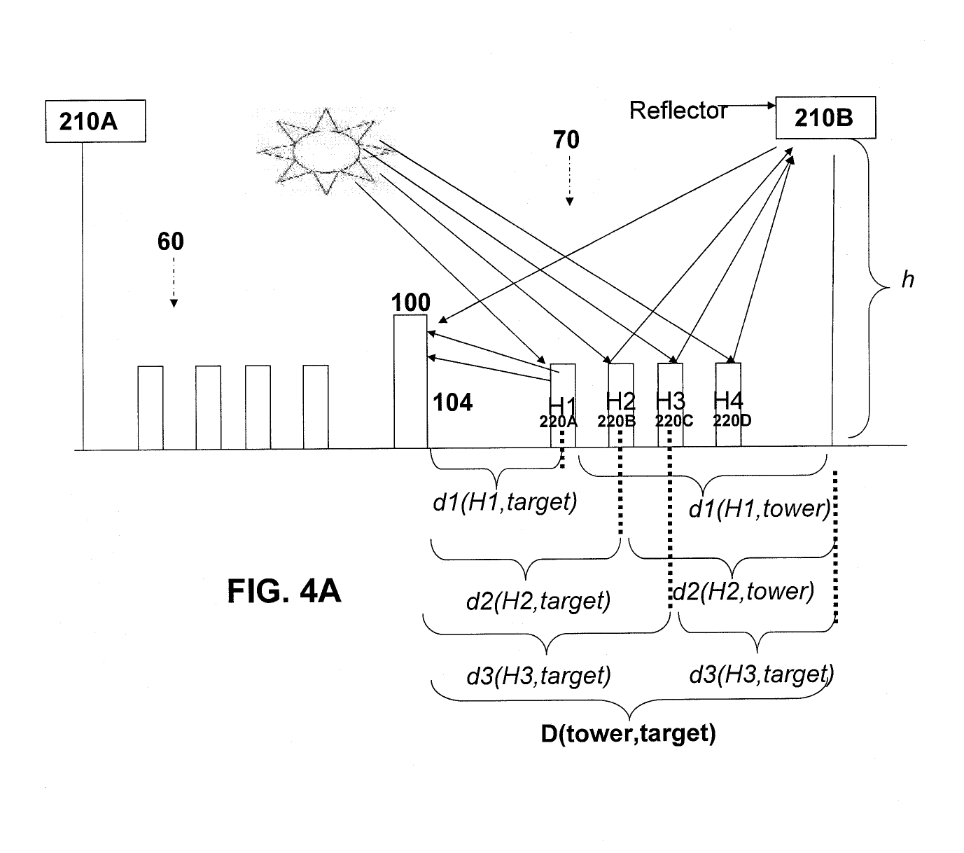

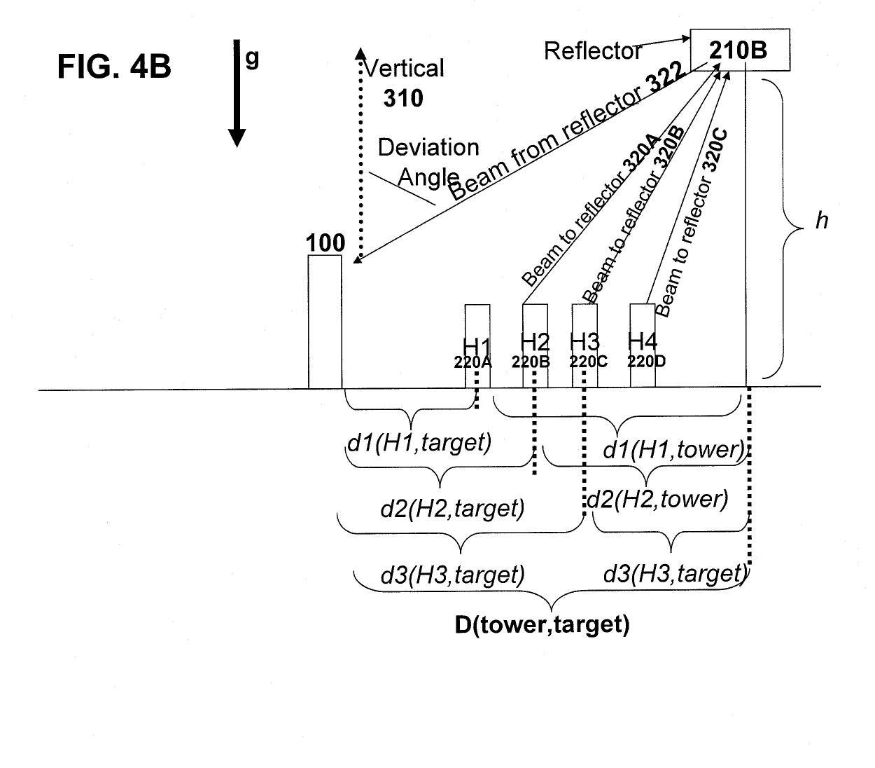

FIGS. 4A-4B illustrate another view of the system including the left 60 and right 70 heliostat fields, the elevated reflectors 210A-210B, and the target. In the non-limiting example, the right heliostat field includes at least 4 heliostats—H1, H2, H3 and H4. H1 reflects sunlight to the target not via reflector 210B—for example, directly. H2-H4 reflect light to the right surface 104 of the target 100 via the right reflector 210B.

As noted before, the height h of either reflector 210A or 210B may be at least 5 or 10 or 20 or 25 or 50 meters. In different embodiments, horizontal distance along the ground D(tower, target) may be at various distances, for example, at least 15 or 25 or 50 or 75 or 100 meters. In some embodiments, horizontal distance along the ground D(tower, target) may be at various distances, for example, approximately 15 or 20 or 25 or 50 or 75 or 100 meters.

The heliostats may be deployed at any location in between 15 and 100 or 200 or 300 meters. In different embodiments, a deviation angle between a line followed by the reflected light beam 320 from the heliostat to the elevated reflector 210 may deviate from the vertical line 310 (which is the gravity vector g) by at least 5 or 10 or 20 or 30 or 50 or 70 degrees and/or at most 10 or 20 or 30 or 50 or 70 or 80 degrees—this deviation angle may depend on the location on the heliostat in the field. For heliostat H2 the deviation angle between 320A and 310 is greater than the deviation angle between 32C and 310 for heliostat H3.

Also illustrated in FIG. 4B is a deviation angle between the beam reflected from reflector 320 and the vertical 310 which may be at least 10 or 20 or 30 or 50 or 70 degrees and/or at most 20 or 30 or 50 or 70 or 80 degrees. There is no limitation on the height of target 100 which may be at least 1, 3, 5 or 10 meters and at most 20, 10, 5, 3, 2 or 1 meters. In some embodiments, heliostats 220 of the left 60 and/or right 70 field are on ground level and/or substantially in a plane. In some embodiments, the elevation of target 100 is substantially the same as the bottom of one or more heliostats 220.

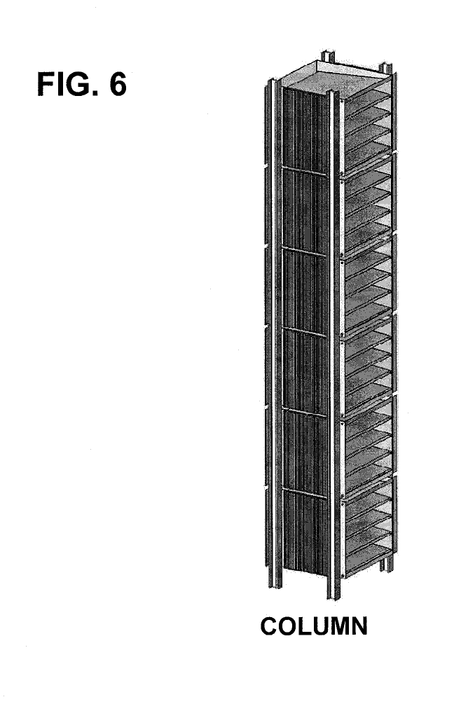

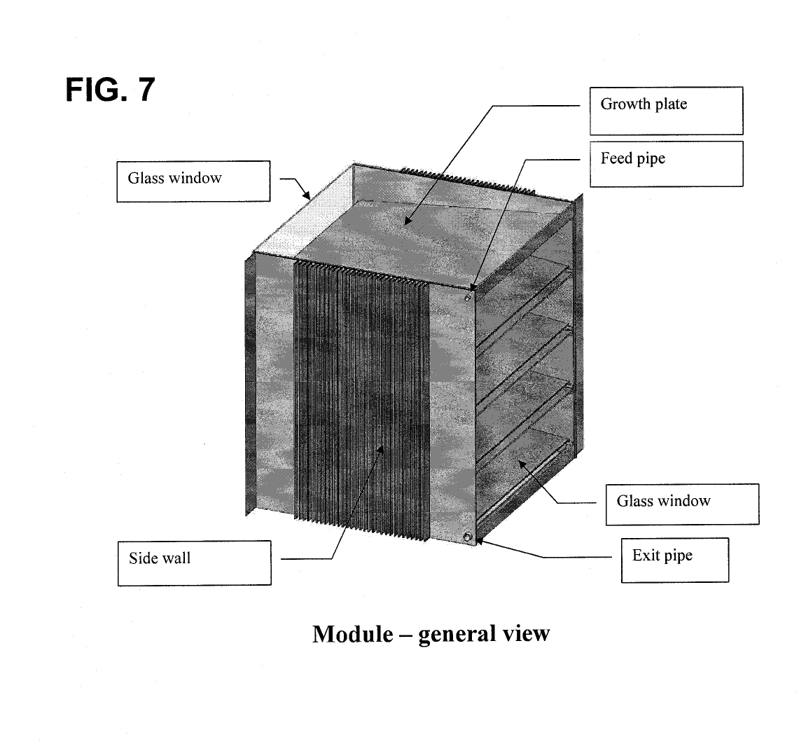

FIG. 5 illustrates a heliostat in non-limiting embodiments. FIG. 6 illustrates a single reactor column. FIG. 7 illustrates a few of a module.

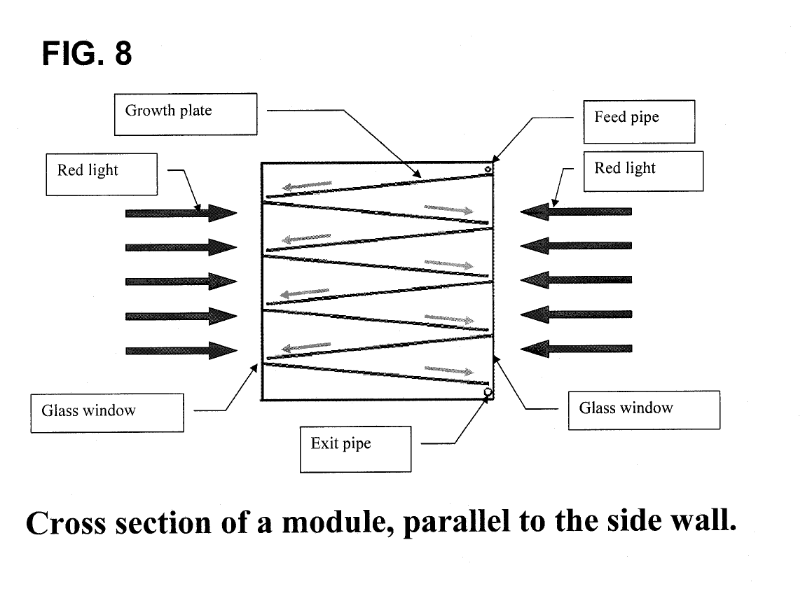

FIG. 8 illustrates a cross section of a module, parallel to the side wall. The feed pipe distributes the bio-solution (containing the BPCs) along the top of the first growth plate. The cyan colored arrows indicate the cascading flow of the bio-solution along the slanted growth plates. The red light (produced by the light management system, section 4) passes through the specially designed glass window on both sides of the module and illuminates the bio solution.

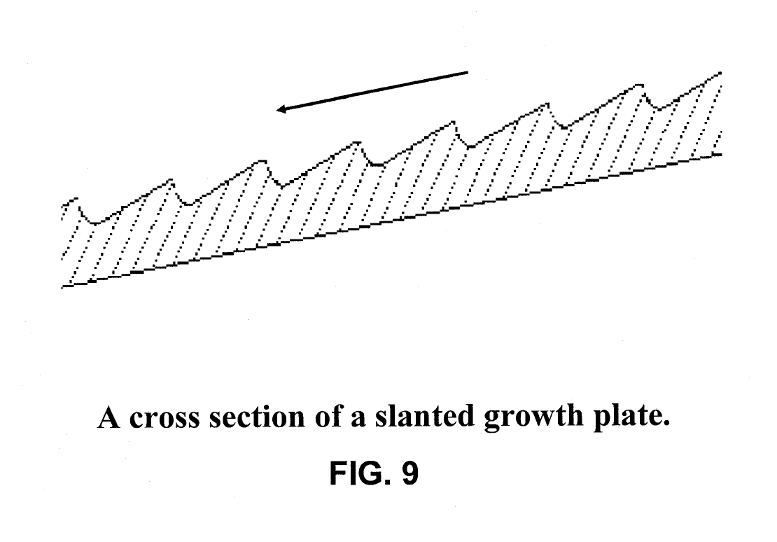

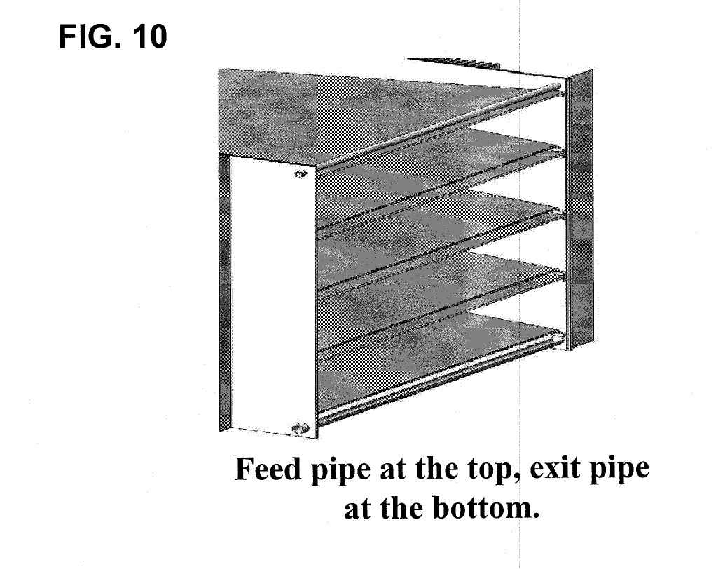

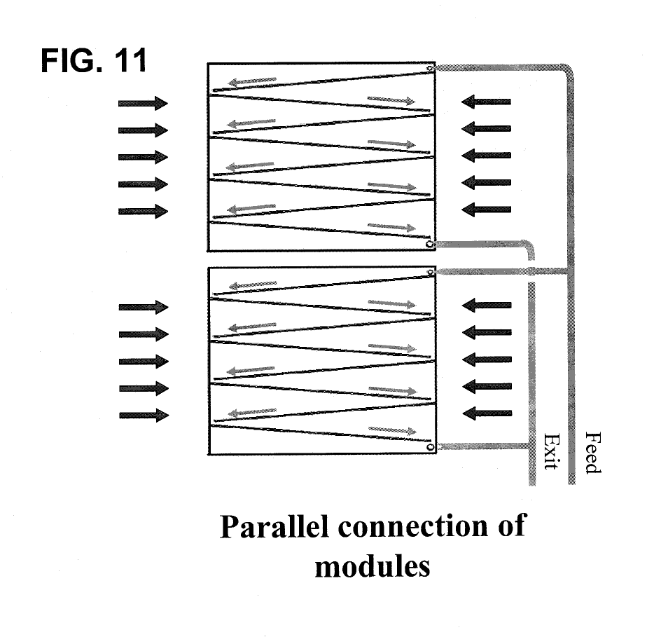

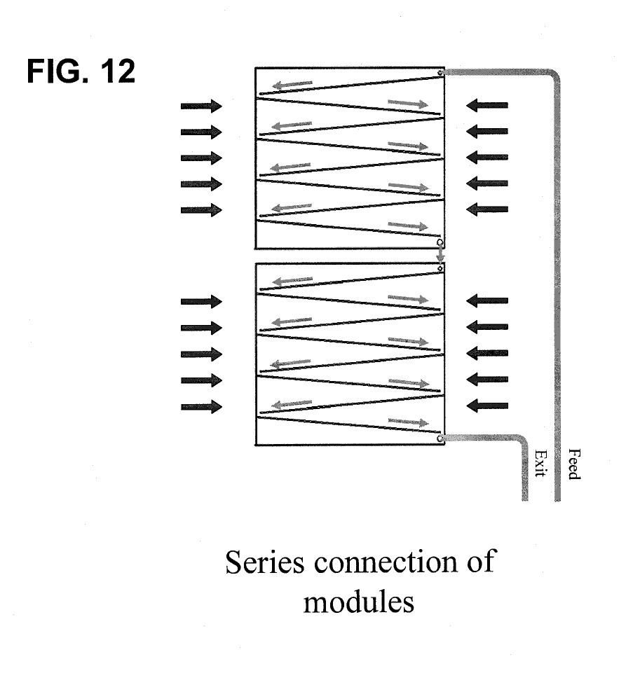

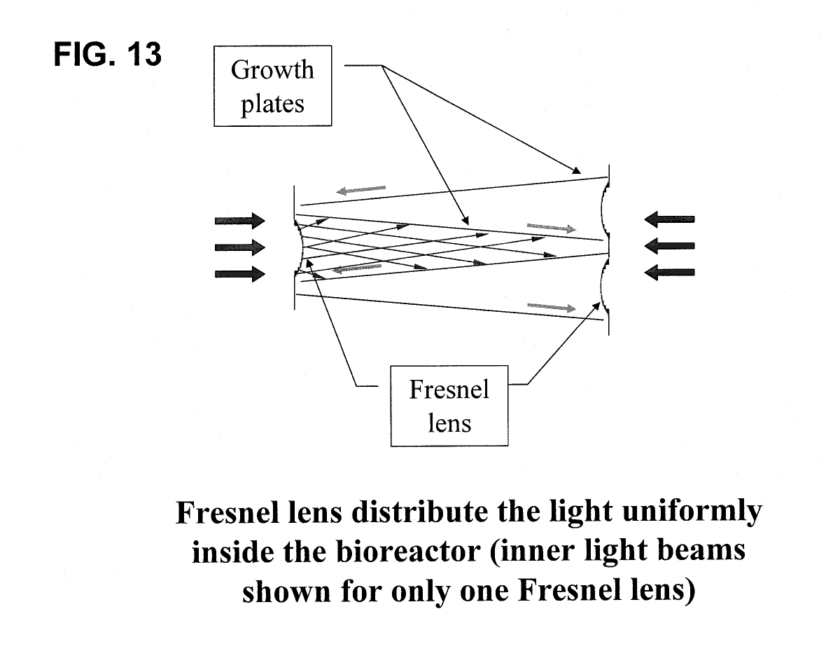

FIG. 9 illustrates a cross section of a slanted growth plate. The arrow indicates the direction of the flow of the bio-solution. FIG. 10 illustrates a feed pipe at the top, and exit pipe at the bottom. FIG. 11 illustrates parallel connection of modules. FIG. 12 illustrates a series connection of modules. FIG. 13 illustrates a Fresnel lens distributing the light substantially uniformly inside the bioreactor (inner light beams shown for only one Fresnel lens).

It is disclosed herein a system for harvesting solar energy, the system includes: a) an elongated upright target (for example, at or near ground level), the elongated upright target including first 102 and second 104 vertical surfaces (for example, elongated vertical surfaces) that face away from each other, b) first and second reflection assemblies located on respective sides of the elongated upright target such that the first reflection assembly is located on the first side of the elongated upright target and the second reflection assembly is located on the second side of the elongated upright target 100, each reflection assembly including: i) a respective field of heliostats (e.g. 60 or 70) located on the respective side of the target; ii) a respective at least partially reflecting element (e.g. 210A or 210B) located above the heliostat field.

In some embodiments, the system is configured such that between A_MINIMUM_PERCENTAGE (for example, 10%) and A_MAXIMUM PERCENTAGE (for example, 50%) of the solar energy impinging upon the heliostats (i.e. either all heliostats of the field and/or all ‘active’ or operational heliostats and/or all heliostats which are directed to the elevated target 120) in a field of heliostats is reflected by the respective reflection assembly onto the respective side of the elongated target.

In some embodiments, the value of the variable A_MINIMUM_PERCENTAGE is 2% or 5% or 10% or 20% or 30% or 50%. In some embodiments, the value of the variable A_MAXIMUM_PERCENTAGE is 10% or 30% or 50% or 70%.

In some embodiments, the reflective element 210 is only partially reflective (for example, spectrally selective).

In some embodiments, a photovoltaic assembly receives some light from the heliostat which traverses a partially reflective element (for example, dichroic mirror—see FIG. 3C).

In some embodiments, the target is a bioreactor for generating biofuel.

In some embodiments, the left and right vertical walls (i.e. vertical walls at surfaces 102 and 104) of the target include an optically diffusive element (for example, a Fresnel lens—see FIG. 13) for distributing light within target 100 (for example, a bioreactor).

In one non-limiting example, incoming light (either directly from the heliostats and/or from the reflecting element 210) is substantially uniformly distributed within target 100. For example, the target may be a bioreactor.

The substantially uniform light distribution may be uniform in the horizontal and/or in the vertical direction.

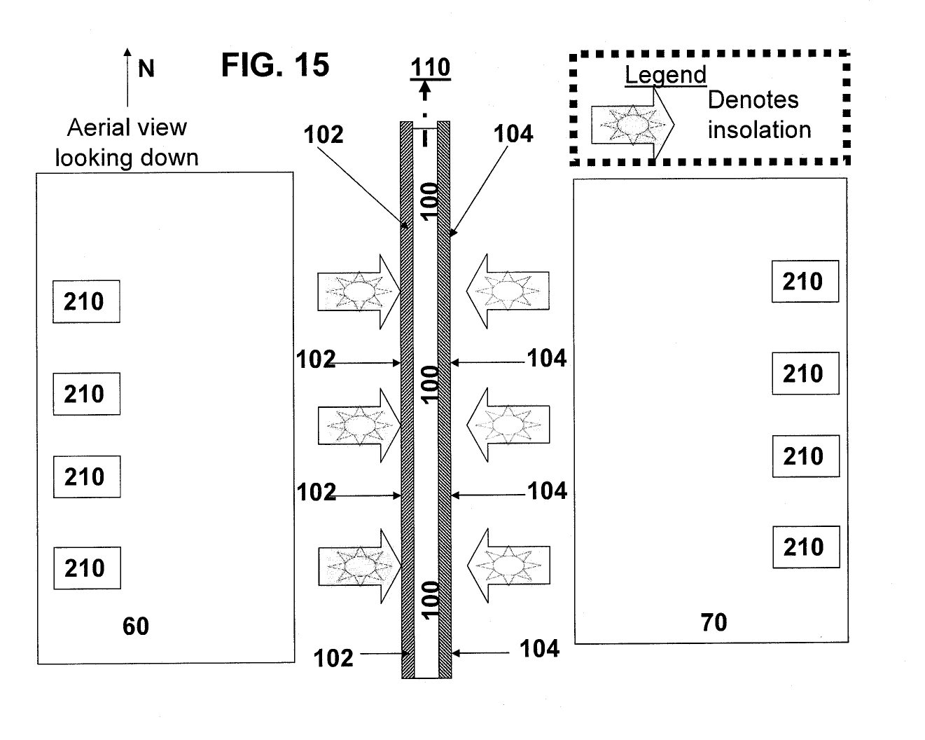

Although only a single reflector 210 on each side (i.e. left and right side) have been illustrated, it is appreciated that more than one reflector may be present on each side—for example, see FIG. 15.

In some embodiments, at least 10 or 15 or 20 or 30 or 40 suns of light are concentrated at each reflector.

In some embodiments (for example see FIG. 3B) at least 10 or 30 or 50 or 70% of the light either: traverses the reflector 210 in an upward direction and/or is reflected in a downward direction at target 100.

The following examples are to be considered merely as illustrative and non-limiting in nature. It will be apparent to one skilled in the art to which the present invention pertains that many modifications, permutations, and variations may be made without departing from the scope of the invention.

### Example I

### Example Butanol Plant

Some embodiments of the disclosed subject matter relate to a butanol plant. It is appreciated that there are many possible implementations, and that none of the features of the example or anywhere in the present disclosure are intended as limiting—all features are illustrative. FIG. 15 is a schematic diagram of a portion of a biofuel plant.

### 1. Example 1

### General Process Description

The following description refers to the “Butanol Photosynthesis Production Process Flow Diagram—Rev B”. Such a plant may produce about 32 metric tons of butanol annually.

1.1. Sunlight Data
As the plant is based on photosynthesis, it can operate only during daytime, and only when the sunlight irradiance is above 300 Watt/m². Based on typical year irradiance data, the relevant parameters for the plant are:
1.1.1. There are about 3350 operational hours in a typical year (hours with sunlight irradiance above 300 Watt/m²).
1.1.2. The maximum sunlight irradiance is 1000 Watt/m², the average sunlight irradiance in the operational hours is 750 Watt/m².
1.1.3. The maximum daily operating time is 13 hours, the most frequent number of hours of operation per day is 12 and the average is 10 operation hours per day.
1.1.4. A typical winter day of 8 operating hours with will be a basis for the pilot plant sizing calculation (see section 5.2.1)

1.2. Main Feedstock Data
1.2.1. The main feedstock (carbon source) of the plant is potassium bicarbonate (KHCO₃). The plant is sized so that it consumes at least 1 ton of potassium bicarbonate in a typical winter day (see 5.1.4). This material is produced off-site in the C-010 CO₂ absorber. In this unit, CO₂ is absorbed from coal-fired power plant or cement factory flue gases into an aqueous solution of potassium carbonate (K₂CO₃), producing potassium bicarbonate (KHCO₃). The material is then trucked to the plant (line 010). In an average operating hour, the plant can consume potassium carbonate at a rate of 125 kg/hour.
1.2.2. The potassium bicarbonate is converted in the C-100 CO₂ generator (on site) to CO₂ gas. The CO₂ gas is cooled and compressed into C-130 CO₂ storage tank. The other reaction product, potassium carbonate, is trucked back off site (line 030) to absorb more CO₂ from flue gas.
1.2.3. The typical contamination present in CO₂ sourced from flue gases, such as nitrate, nitrite, sulfate, sulfite, and sulfide compounds might serve as sources of nitrogen and sulfur for the BPCs, and might reduce the amount of required nutrients. (See 5.4.5, 5.4.8)

1.3. Cyanobacteria Growth Areas
There are three areas in the plant where cyanobacteria grow: the LAB-600 Sterile lab, the R-250 Nursery bioreactor and the R-200 Butanol bioreactor.
1.3.1. The LAB-600 Sterile lab is a small, safe storage of the genetically engineered cyanobacteria strain. A small amount of cyanobacteria (typically 10-20 g dry matter) is periodically taken from the LAB-600 Sterile lab to start the butanol production process. The lab will be installed in a 30-50 m² air conditioned area. The lab equipment will include:
   1.3.1.1. One or two 500 liter temperature controlled incubators fitted with lighting devices.
   1.3.1.2. Standard lab glassware. (About 50 different pieces).
   1.3.1.3. Sterilization equipment.
1.3.2. The R-250 Nursery bioreactor is a set of 6 columns (see 3.2) operating together. The R-250 Nursery is used to grow the small amount of cyanobacteria taken out of the LAB-600 Sterile lab into 25-30 kg dry matter.
1.3.3. The R-200 Butanol bioreactor is a set of 90 columns (see 3.2) operating together. The R-200 Butanol bioreactor is used mainly for butanol production.

1.4. Main Operation Sequences
1.4.1. To start the operation of the plant, the LAB-600 Sterile lab will receive the genetically engineered Butanol Producing Cyanobacteria (BPC) from the developer (see 1.1).
1.4.2. The LAB-600 Sterile lab will grow the BPCs in the incubators, and about once a month supply a starting dose of BPCs (10-20 g dry matter) to the R-250 Nursery bioreactor.
1.4.3. Plant operators will prepare (once a month, see 5.4.12) the starting bio-solution in T-220 Bio-solution tank by mixing ˜1400 liters of water (taken from T-500 Process water tank—line not shown) with up to 10 kg of potassium carbonate until pH of 9.5±0.5 is reached. To this bio-solution the operator will add the starting dose (10-20 g dry matter) of BPC taken from LAB-600 Sterile lab via a hopper installed on the T-220 Bio-solution tank. As required by lab tests of the water in T-500 Process water tank, plant operators might add to T-220 Bio-solution tank small amounts (typically 0.1 to 5 g) of the following materials: K₂HPO₄, MgSO₄.7H₂O, CaCl₂.2H₂O, H₂BO₃, MnCl₂.4H₂O, ZnSO₄.7H₂O, Na₂MoO₄.2H₂O, CuSO₄.5H₂O, Co(NO₃)₂.6H₂O.
1.4.4. In the morning, as soon as direct solar irradiance reaches 300 Watt/m², plant operators will start P-261 Nursery circulation pump, thus starting the circulation of the bio-solution on the growth plates of the R-250 Nursery bioreactor. In parallel, the control system of the HS-270 Heliostat field will adjust the heliostats to follow the sun and direct red light (see section 4) onto the glass windows of the R-250 Nursery bioreactor. At sunset, as irradiance drops below 300 Watt/m², plant operators will shut down P-261 Nursery circulation pump, letting the bio-solution drain by gravity back to T-220 Bio-solution tank for the night. Plant operators will take a sample of the bio-solution, measure the BPC density and calculate the total BPC mass to monitor the growth rate of the BPC and determine the nutrients and CO₂ requirements (see 5.4.5). This procedure will continue for several days (11 to 16 days, depending on weather conditions) until the BPC dry mass in the nursery section (T-220 Bio-solution tank, R-250 Nursery bioreactor and the connecting pipes) reaches about 30 kg.
1.4.5. Based on the BPC dry mass measured in T-220 Bio-solution tank (see 5.4.4), plant operators will calculate amounts of NH₃, CO₂ and water that must be added to the bio-solution to sustain the growth of the BPCs. This calculation will take into account the amount of nitrogen available from contamination in the CO₂ (see 5.2.3). Based on these calculations, the plant operators will set the P-292 NH₃ dosing pump and the CO₂ control valve on line 306. For more details see 5.6.
1.4.6. As the BPC dry mass in the nursery section reaches about 30 kg, the plant operators will prepare the starting bio-solution in T-310 Bio-solution tank by mixing about 13,000 liter of water (taken from T-500 Process water tank—line not shown on the PFD) with up to 70 kg potassium carbonate until pH of 9.5±0.5 is reached. As required by lab tests of the water in T-500 Process water tank, plant operators might add to T-310 Bio-solution tank small amounts (typically 1 to 50 g) of the following materials: K₂HPO₄, MgSO₄.7H₂O, CaCl₂.2H₂O, H₂BO₃, MnCl₂.4H₂O, ZnSO₄.7H₂O, Na₂MoO₄.2H₂O, CuSO₄.5H₂O, Co(NO₃)₂.6H₂O. Then, utilizing P-261 Nursery circulation pump and the valves on line 260, plant operators will transfer the ˜1400 liters of bio-solution (containing ˜30 kg dry matter of BPCs) from T-220 Bio-solution tank to T-310 Bio-solution storage tank. (In tank T310 we have now 14,400 liters of bio-solution at ˜2 g/l BPC).
1.4.7. During the first day, the R-200 butanol bioreactor will be used to increase the BPC dry matter from ˜30 kg (˜2 g/liter) to about ˜85 kg (˜5.9 g/liter). For that purpose, in the morning, as soon as direct solar irradiance reaches 300 Watt/m², plant operators will start P-325 Bio-solution circulation pump, thus starting the circulation of the bio-solution on the growth plates of the R-200 Butanol bioreactor. In parallel, the control system of the HS-270 Heliostat field will adjust the heliostats to follow the sun and direct red light (see section 4) onto the glass windows of the R-200 Butanol bioreactor. At sunset, as irradiance drops below 300 Watt/m², plant operators will shut down P-325 Bio-solution circulation pump, letting the bio-solution drain by gravity back to T-310 Bio-solution tank for the night. Plant operators will take three times a day samples of the bio-solution from T-310 Bio-solution tank, measure the BPC density and calculate the total BPC mass to monitor the growth rate of the BPC and determine the nutrients and CO₂ requirements (see 5.4.8). This procedure will continue (typically 1-2 days, depending on weather conditions) until the BPC dry mass in the bio-solution reaches about 85 kg (˜5.9 g/liter). Process will then proceed per section 5.4.9 below.
1.4.8. Based on the BPC dry mass measured in T-310 Bio-solution tank (see 5.4.7), plant operators will calculate amounts of NH₃, CO₂ and water that must be added to the bio-solution to sustain the growth of the BPCs. This calculation will take into account the amount of nitrogen available form contamination in the CO₂ (see 5.2.3). Based on these calculations, the plant operators will set the P-291 NH₃ dosing pump, the P-321 carbonator feed pump and the CO₂ control valve on line 302. And add water periodically For more details see 5.6
1.4.9. As the condition specified in the end of section 5.4.7 above is met (BPC dry mass in the bio-solution reaches about 85 kg (˜5.9 g/liter)), plant operators will shut down P-291 NH₃ dosing pump, turn on P-296 HNO₃ dosing pump and feed about 15 kg of HNO₃ into the bio-solution. This operation will activate the BPCs to stop their growth and start producing butanol. The butanol production rate will be about 10 kg/hour. Plant operator will continue to operate this section as before: In the morning, as soon as direct solar irradiance reaches 300 Watt/m², plant operators will start P-325 Bio-solution circulation pump, thus starting the circulation of the bio-solution on the growth plates of the R-200 Butanol bioreactor. In parallel, the control system of the HS-270 Heliostat field will adjust the heliostats to follow the sun and direct red light (see section 4) onto the glass windows of the R-200 butanol bioreactor. At sunset, as irradiance drops below 300 Watt/m², plant operators will shut down P-325 Bio-solution circulation pump, letting the bio-solution drain by gravity back to T-310 bio-solution tank for the night. Plant operators will take three times a day samples of the bio-solution from T-310 Bio-solution tank, measure the BPCs density, the HNO₃ density and butanol density. Based on these densities, plant operators will determine BPC's condition and density, the nutrients and CO₂ requirements, and the required butanol removal rate. (See 5.4.10). This procedure will continue (typically for 30 days, depending on weather conditions) until the BPC population starts to die out (As indicated by the results obtained from the samples).
1.4.10. Based on the BPC and butanol densities measured in T-310 Bio-solution tank (see 5.4.9), plant operators will calculate the following parameters (For more details see 5.6):
   1.4.10.1. The amount of HNO₃ that is needed to maintain the HNO₃ concentration within the required limits (0.6±0.4 g/liter). Based on the result, the operator will adjust the P-296 HNO₃ dosing pump as required. Note: HNO₃ is not consumed by the BPCs, and its concentration may only need periodic corrections.
   1.4.10.2.The amount of CO2 required for the production of butanol. Based on the result, the operators will adjust the CO2 control valve on line 304. The set point for CO2 feed rate is ˜24 kg/hour.
   1.4.10.3. The amount of water required (water is consumed by the photosynthesis process). Plant operators will add process water periodically as required.
   1.4.10.4. The amount of butanol that need to be removed from the bio-solution. Based on the result, the operator will adjust P-315 Stripping feed pump and the CO₂ control valve on line 304. Note: Above a certain level, butanol is toxic to the BPCs. The butanol stripping sub-system (based around C-300 Butanol striping unit) is designed to maintain the butanol level well below the toxic limit.
1.4.11. As the BPCs start to die out and the butanol production rate drops, the plant operators will utilize P-325 Bio-solution circulation pump and the valves on lines 200 and 501 to remove the all the bio-solution to T-550 Spent solution tank, and wash the butanol producing section. (See 5.5.2 for the treatment of the spent bio-solution). Now the butanol section is ready for the next batch of BPC (see 5.4.12 below)

1.5. Supporting Operations
1.5.1. The water supply of the plant comes from the local municipal water system to T-590 Water tank. P-531 City water pump pumps the water to T-500 Process water tank via E-520 Water heat exchanger (115° C.—for reduction of the bacteria population in the water). The plant operators check water quality daily. If needed, P-510 Process water pump will circulate the process water via E-520 Water heat exchanger.
1.5.2. Spent bio-solution (about 14,400 liters of water containing about 85 kg of dead/dying PCBs) is transferred to T-550 Spent solution tank once a month. (See 5.4.11). P-555 Spent solution pump pumps the solution via S-560 Clarifier to T-570 Solution to recycle tank. P-565 Sludge pump will remove from the bottom of the clarifier concentrated PCB sludge (˜900 liters containing 85 kg of dead PCBs). This sludge will be sold as a raw material for biogas production. The RO-580 Reverse osmosis unit (pump and filters included in this unit) will be utilized to reduce salts concentration in T-570 Solution to recycle tank. Plant operators will monitor the water quality in T-570 Solution to recycle tank daily, and when water quality is acceptable, P-575 Solution to recycle pump will pump the water to T-500 Process water tank. The brine stream is estimated at 100-300 liter per month. The brine will be analyzed and may be reused by the plant for starting preparation of the bio-solution.

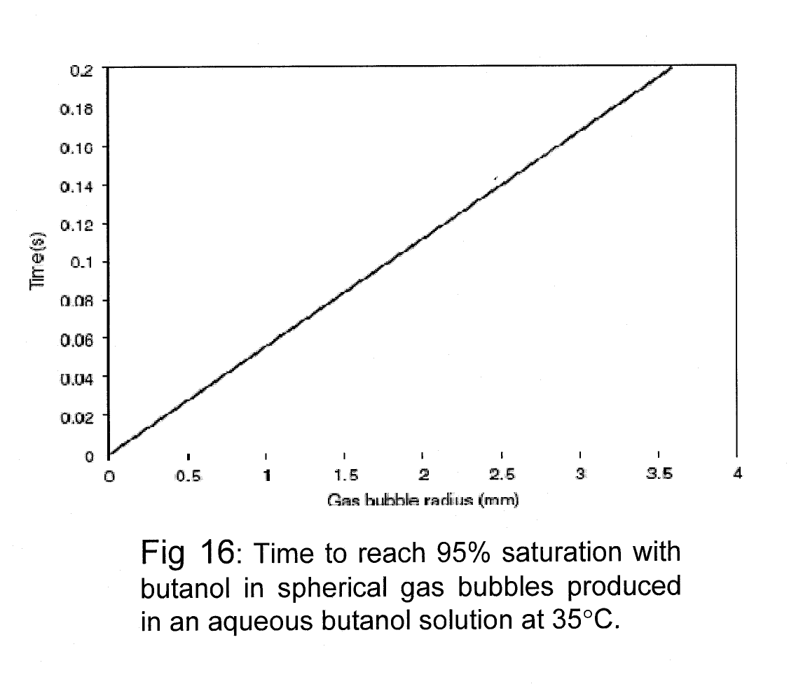

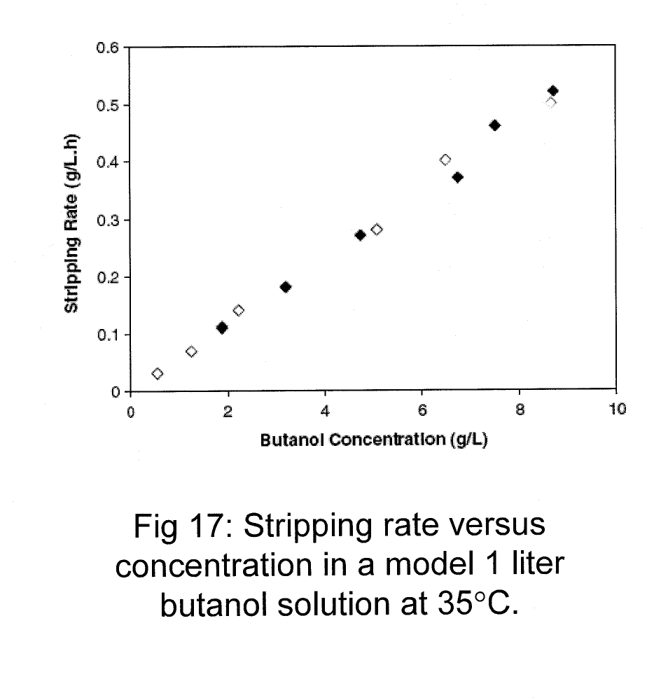

Butanol is separated from the bio-solution by the gas stripping method. In this method, gas is bubbled through the bio-solution, causing some butanol vapor to be carried with the gas out of the solution. The butanol can then be separated from the gas either by condensation or by membrane. Ezeji et al. (Bioprocess Biosyst Eng 27:207-214 (2005)) provide the basic data of the butanol stripping process, which is presented here in FIGS. 16-17.

FIG. 16 shows the time to reach 95% saturation with butanol in spherical gas bubbles produced in an aqueous butanol solution at 35° C.

FIG. 17 shows the stripping rate versus concentration in a model 1 liter butanol solution at 35° C. Two gas bubble delivery systems, impeller (open diamond) and sparger (filled diamond) were used. Gas (N2, CO2 and H2) flow rate was 80 cm³/s gas recycle

From FIG. 16, it can be seen that butanol “fills up” the bubbles within a very short time, even for large (diameter=5 mm) bubbles. This means that the C-300 Butanol stripping unit can be as shallow as 10 cm and can use large bubbles, thus reducing the blower power requirements.

FIG. 17 provides the basic data for butanol gas stripping. Based on these data it can be shown that at 35° C., and butanol concentration of 0.6% (6 g/liter), each liter of gas strips out of the solution ˜1.73 mg of butanol. The amount of butanol that is stripped out of solution by a liter of gas is proportional to both the butanol concentration in the solution and to the butanol vapor pressure. Based on the butanol vapor pressure at the plant's design temperature (55° C.) and the designed butanol concentration (0.4%), some 2,100 m³/hour of gas are required to strip the 9.9 kg/hour butanol produced by the plant.

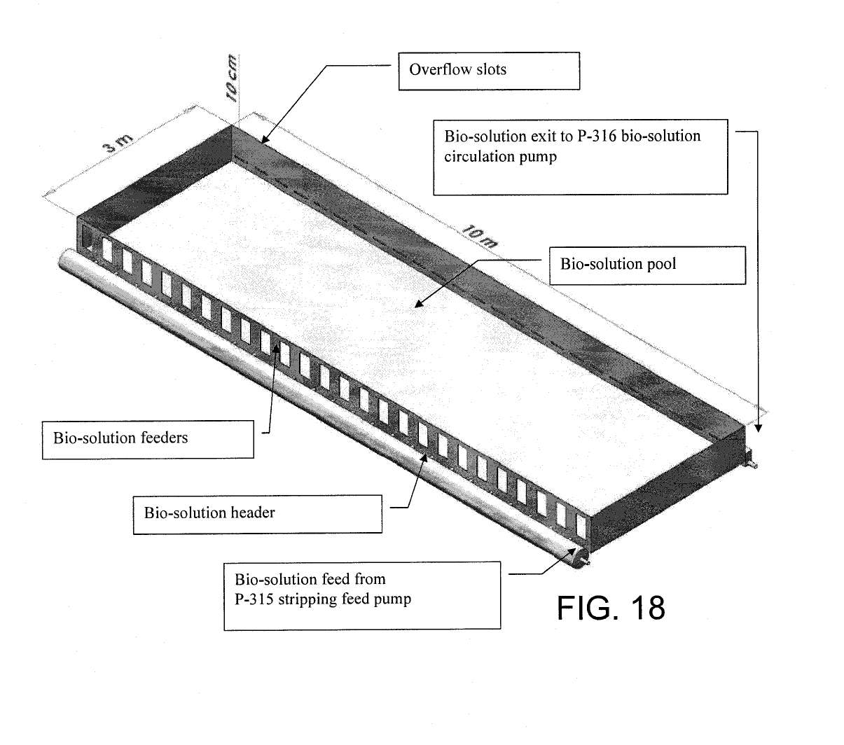

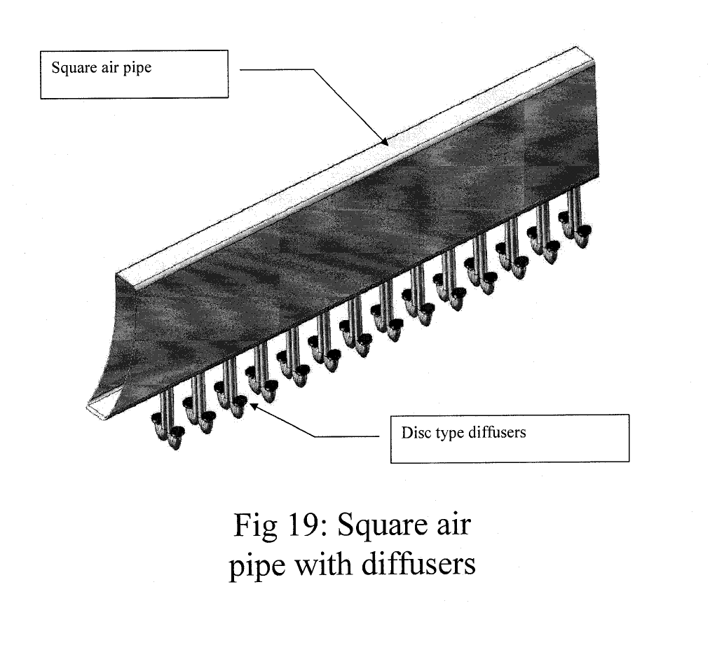

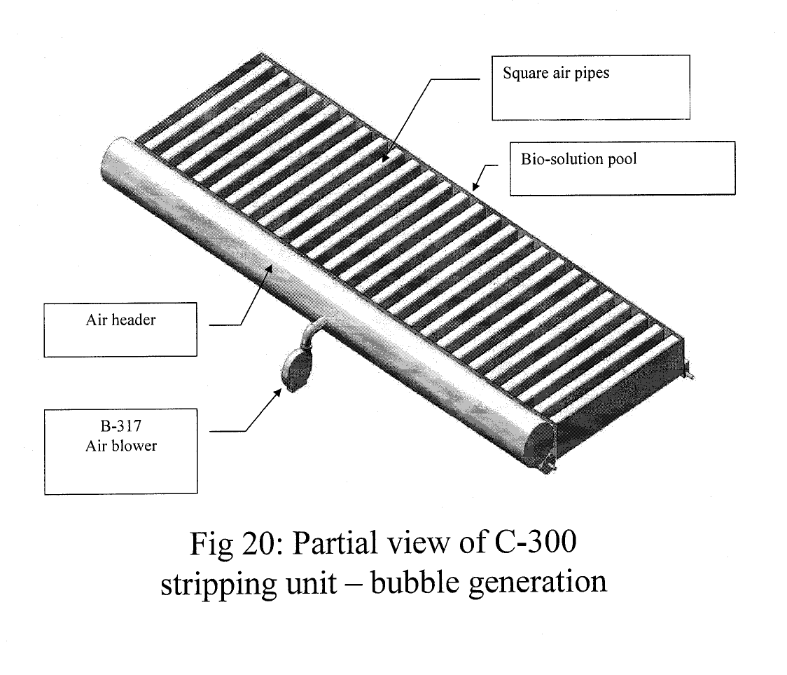

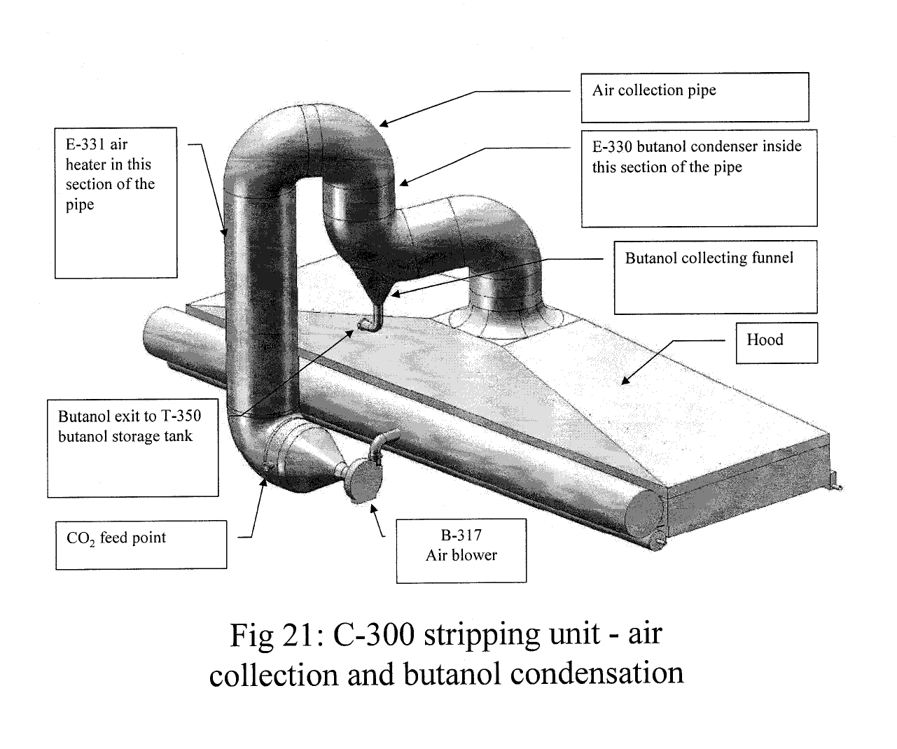

The C-300 Butanol striping unit is illustrated in FIGS. 18-21. FIG. 18 shows the bio-solution pass into the stripper. FIG. 18 illustrates a partial view of C-300 stripping unit—the bio-solution path. FIG. 19 shows a square air pipe with 28 disc-type air diffusers mounted on it. When the diffusers are immersed in water and fed with air, each disc can produce air bubbles at a rate of ˜3 m³/hour. FIG. 20 shows the bubble generation in the C-300 stripping unit. The B-317 air blower feeds some 2,100 m³/hour of air into the air header. Then the air flows into 26 square pipes (FIG. 19). Each square pipe feeds 28 disc-type air diffusers immersed in the bio-solution in the bio-solution pool (see FIG. 18). This 728 diffusers bubble the air through the 10 cm layer of bio-solution, stripping the bio-solution of the butanol. The air (and the butanol vapor) goes up between the square pipes and is collected by a hood (FIG. 21).

Pump P-315 feed the bio-solution into the large diameter bio-solution header, and then it flows via the small diameter feeders into the central 3 m by 10 m pool. The overflow slots, located 10 cm above the pool bottom, maintain the bio-solution level in the pool at 10 cm, with excess bio-solution flowing through the overflow slots into a duct, and then being pumped away by P-316 via the exit pipe.

FIG. 21 shows the path of the striping air: The hood directs the air into the air collection pipe. The E-330 butanol condenser is located inside the first section of the air collection pipe. This condenser is cooled to about ˜5° (cooling system not shown in FIG. 21). As the air and the butanol vapor pass through the condenser, the butanol vapor condenses, together with some water vapor. The air flows on, heated by the E-331 air heated back to the 55° C. operation temperature, into the suction port of the B-317 air blower. The condensate drips down and is collected by the butanol funnel, and flows through the butanol exit to T-350 butanol storage tank. Some 9.9 kg/hour of butanol, together with 165 kg/hour of water, flows into T-350 butanol storage tank. This water/butanol mixture is pumped by P-318 filtration feed pump into FL-319 micro-filtration unit were most of the water are filtered out and returned to T-310 bio-solution tank. The remaining water/butanol concentrate is left overnight in the tank. Most of the butanol product will float over the water. (Butanol/water dissolution limit is 9%) In the next morning the butanol product will be pumped out by the P-308 butanol product pump.

Plant operators will set the control valve on the 304 CO₂ line, to adjust the flow rate of CO₂ into the stripping air stream through the CO₂ feed point (FIG. 21) per the BPC requirements of about 24 kg/hour (see 5.5.4).
1.5.3. The C-260 and C-320 carbonators will feed CO2 into the bio-solution. (C-320 is used only during the growth phase of the butanol section, when the C-300 butanol striping unit is not operating). The rate of CO2 feed is adjustable by the P-261 Carbonator nursery pump/CO₂ control valve on line 306 and P-321 Carbonator nursery pump/CO₂ control valve on line 302, respectively. The plant operators will adjust these units so as to optimize the flow rate of the bio-solution down the carbonators relative to the upward flow of CO₂ bubbles. As the bio-solution is at pH of 9.5±0.5, and contain 0.5% of potassium carbonate, the solubility limit of CO₂ in the bio-solution is much higher then in water, and is estimated at 0.2 mol/liter (about 9 g/liter). The CO₂ requirement of the PCBs in the bio-solution depends on their concentration.
   1.5.3.1. In the R-250 Nursery bioreactor, CO₂ requirements during most of the growth period are very low, (the starting PCBs concentration is 0.01 g/liter, and it will be well below 0.1 g/liter for most of the first week). So in the first week, the BPCs in the R-250 Nursery bioreactor will feed the CO₂ available in the solution, and the C-260 and carbonator will be put to use periodically during the second week, reaching full operation only by the end of the second week. It is therefore assumed that the CO₂ requirements of the PCBs in the R-250 Nursery bioreactor are negligible compared with the requirements of the R-200 Butanol bio reactor.
   1.5.3.2. The PCBs in the R-200 Butanol bioreactor will receive their CO₂ supply the C-300 Butanol striping unit. The C-320 carbonator will only operate during the 1 day of the growth phase of the R-200 Butanol bioreactor. CO₂ feed rate will be about 24 kg/hour.
1.5.4. Nitrogen is entered into the bio-solution either from tank T-290 NH₃ tank via P-291/P-292 NH₃ Dosing pumps or from tank T-295 HNO₃ tank via P-291/P-292 HNO₃ Dosing pumps. (Note: HNO₃ may be replaced by NaNO₃ or KNO₃). The content of T-290 and T-295 will be aqueous solutions of NH₃ and HNO₃, respectively. Here again the feed rate of these dosing pumps depends on the BPCs concentration and on the available nitrogen that comes as contamination of the CO₂ supply.

1.6. Mass Balance Detailed Data
As seen in FIG. 15, the butanol pilot plant operation is organized in 31 “day” cycles (“Day”=12 hours of operation). For example, there can be 9 such cycles each year (in the rest of the time, weather conditions prevents the operation of the plant). Following a short review of the module operation data, mass and energy data both on a “per hour” basis and on a “per cycle” basis are presented.
1.6.1. Module. The basic building block of the plant is the module (see section 3.1). Two set of biochemical reactions take place in the module: reaction that produce bio-mass and reaction that produce butanol. Both these set of reaction are highly complicated, but for the purpose of an overall description of the module operation they can be summarize as follows:
   1.6.1.1. Bio-mass production (driven by 24 photons):

0.508.H₂O+CO₂+0.188.NH₃→(dry)biomass+1.054.O₂
where the (dry) biomass is made of 51.38% C, 6.8% H, 11.29% N, 27.51% 0, and 3.3% other material (magnesium, iron, calcium, phosphorus, sulfur, and so on). Based on this composition, the “molecular weight” of the dry biomass can be 22.62.
1.6.1.2. Butanol (C₄H₉OH) production (driven by 48 photons):

5.H₂O+4.CO₂→C₄H₉OH+6.O₂
In parallel, some 16 photons drive “cell maintenance” bio-reactions, which have no net effect on the bio-mass.
1.6.2. The general process data for the module are:

| Description | Value | Units |
|---|---|---|
| Bio-solution volume | 16 | liter |
| Residence time | 267 | sec. |
| Bio-solution flow rate | 216 | liter/hour |
| Solar radiation power* | 780 | Watt |
| Maximum operating temperature | 55 | ° C. |

*The average solar radiation power that enters the module via its two side windows is in the “red” window of the spectrum (~600-700 nm), which constitutes about 13% of the total power solar radiation power. The excess heat is dissipated from the module to the outside atmosphere via the cooling ribs mounted on the two side walls (see FIG. 2). No forced ventilation is needed, as the required heat transfer rate through the side walls is below 0.05 W/cm².

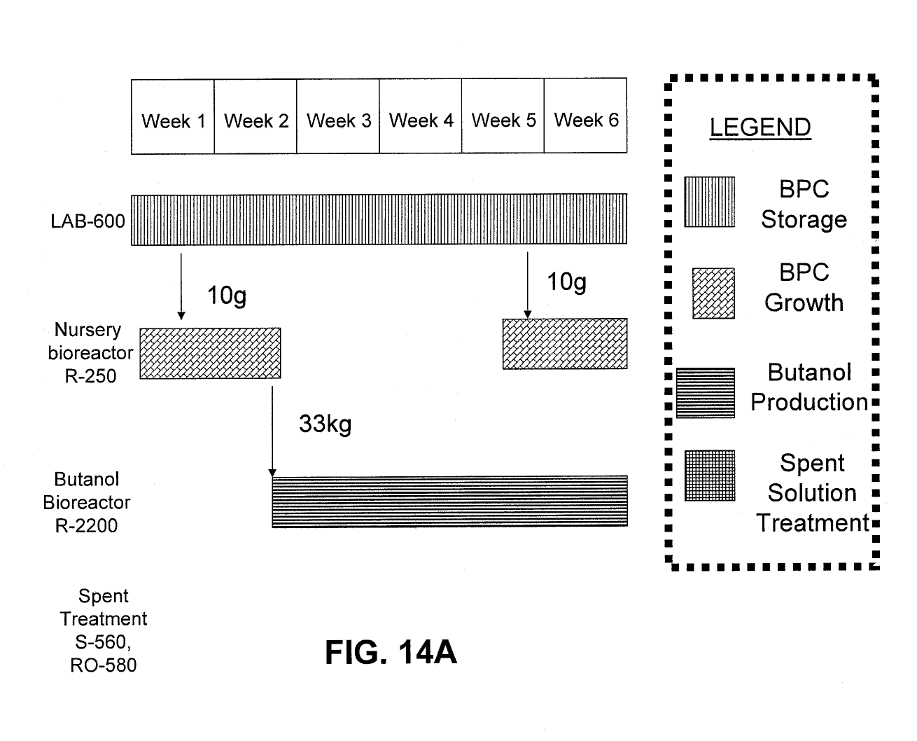

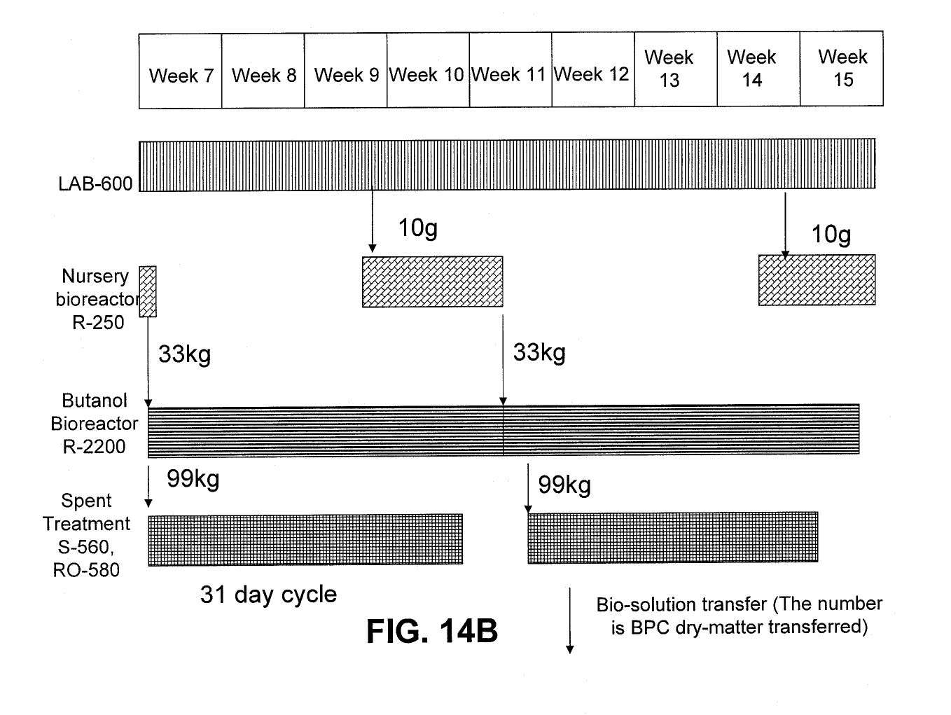

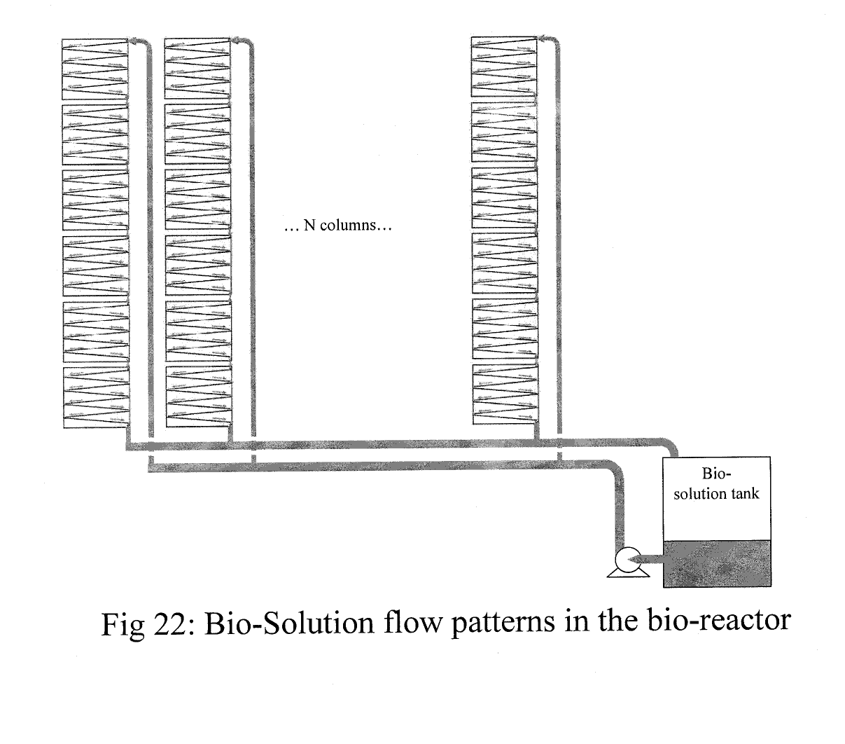

1.6.3. Bio reactor. As explained in section 3, 6 modules are stacked on top of each other to produce a column, and a line of N columns operating together make up a bioreactor. The bio-solution flow patterns in the bioreactor are presented in FIG. 22. In a butanol pilot plant, there can be two bioreactors: The R-200 Butanol bio-reactor (90 columns) and the R-250 Nursery bio-reactor (6 columns).
1.6.4. Nursery section. As seen in FIGS. 14A-14B, the R-250 nursery bio-reactor operates for ˜12 “days” per cycle. During that time the R-250 nursery bio-reactor grows 10 g of PCBs into ˜31 kg of PCBs (dry mass).
   1.6.4.1.The operations data of the “nursery section” (R-250, P261, T-220) are presented below:

| Description (nursery section) | Value | Units |
|---|---|---|
| Starting BPCs dry mass | 10 | Gram |
| Operation “days” | 11.5 | “days” |
| Operation hours | 144 | Hours |
| Bio solution volume (in R-250, T-220, C-260 and | 1.440 | m³ |
| pipes) | | |
| Nursery circulation pump P-261 rate | 1.3 | m³/hour |
| Nursery circulation pump P-261 pressure | 2 | Bar |
| Final BPCs dry mass | 31 | Kg |

1.6.4.2. Data from the mass balance of the “nursery section” (R-250, P261, T-220) are presented below. (Note that as the growth is exponential, only in last 2-3 days is there considerable growth and a corresponding need for nutrient (CO₂, NH₃) supply):

Materials (nursery section)

| Description | H₂O | CO₂ | NH₃ | Biomass | O₂ | Units |
|---|---|---|---|---|---|---|
| Total (cycle) | −12.52 | −60.68 | −4.38 | 30.98 | 50.34 | Kg |

1.6.5. Butanol section. After the BPCs are transferred from the T220 (in the nursery section) to T310 (see 5.4.6), they are now in the “butanol section” (R-200, T310, P325). In the butanol section the BPCs will continue to grow for one more day (“growth phase”), and then NH₃ is replaced by HNO₃, triggering the butanol production. The butanol production will go on for 30 days, after which the BPCs will be transferred to the T-550 Spent solution tank and a fresh BPC batch will enter the butanol section.
   1.6.5.1. The operations data of the “butanol section” (R-200, P325, T-310) during the growth phase are presented below:

| Description (butanol section, growth phase) | Value | Units |
|---|---|---|
| Starting BPCs dry mass | 30.98 | Kg |
| Operation “days” | 1 | “days” |
| Operation hours | 12.09 | Hours |
| Bio solution volume (in R-250, T-220, C-260 and | 14.410 | m³ |
| pipes) | | |
| Circulation pump P-325 rate | 19.44 | m³/hour |
| Circulation pump P-325 pressure | 2 | Bar |
| Final BPCs dry mass | 84.79 | Kg |

1.6.5.2. Data from the mass balance of the “butanol section” (R-250, P261, T-220) during the 1 day “growth phase” are presented below:

Materials (butanol section, growth phase)

| Description | H₂O | CO₂ | NH₃ | Biomass | O₂ | Units |
|---|---|---|---|---|---|---|
| Total (cycle) | −21.75 | −104.67 | −7.6 | 53.81 | 80.24 | Kg |

1.6.5.3. The operations data of the “butanol section” (R-200, P325, T-310) during the butanol production phase are presented below:

| Description (butanol production phase) | Value | Units |
|---|---|---|
| BPCs dry mass | 84.79 | Kg |
| Operation “days” | 30 | “days” |
| Bio-solution volume (in R-250, T-220, C-260 and | 14.410 | m³ |
| connecting pipes) | | |
| Circulation pump P-325 rate | 19.44 | m³/hour |
| Circulation pump P-325 pressure | 2 | Bar |

1.6.5.4. Data from the mass balance of the “butanol section” (R-200, P325, T-310) during the 30 days of the butanol production are presented below. (Note: 1 ton=1000 kg):

Materials (butanol production phase)

| Description | H₂O | CO₂ | C₄H₉OH | O₂ | Units |
|---|---|---|---|---|---|
| Rate | −12.2 | −24.1 | 10.02 | 26.0 | kg/hour |
| Total (cycle) | −4.38 | −8.58 | 3.61 | 9.36 | Ton |

1.6.6. Stripping section. In parallel to the butanol production in the bioreactor R-200, butanol is removed from the bio-solution in the “stripping section” (see 5.5.3). Below are the operation data of this section.

| Description (butanol stripping) | Value | Units |
|---|---|---|
| Stripping feed pump P-315 rate | 12 | m³/hour |
| Stripping feed pump P-315 pressure | 0.5 | Bar |
| Bio-solution circulation pump P-316 rate | 12 | m³/hour |
| Bio-solution circulation pump P-316 pressure | 2 | Bar |
| Air blower B-317 rate | 2,100 | m³/hour |
| Air blower B-317 pressure | 0.5 | Bar |
| Filtration feed pump P-318 rate | 0.2 | m³/hour |
| Filtration feed pump P-318 pressure | 8 | Bar |
| Butanol product pump P-308 rate | 1 | m³/hour |
| Butanol product pump P-308 pressure | 1 | Bar |

1.6.7. Carbonators section. The purpose of the carbonators it to feed CO₂ into the bio-solution. The “carbonator section” (P-251 nursery carbonator feed pump, C-260 Nursery carbonator, P-321 carbonator feed pump, C-320 carbonator) provides the required CO₂ only during the growth phase; The CO₂ needed for the butanol production enters the bio-solution via the C-300 butanol stripping unit. During most of the growth time the CO₂ demand is very low, so the carbonator will operate intermittently. The relevant operation data are presented below:

| Description (carbonators section) | Value | Units |
|---|---|---|
| Nursery carbonator feed pump P-251 rate | 0.25 | m³/hour |
| Nursery carbonator feed pump P-251 pressure | 5 | bar |
| Pump P-251 operation time (per cycle) | 36 | hour |
| Carbonator feed pump P-321 rate | 5 | m³/hour |
| Carbonator feed pump P-321 pressure | 5 | bar |
| Pump P-321 operation time (per cycle) | 10 | hour |

1.6.8. Nutrient section. The “nutrient section” (T290 NH₃ tank, P-291 NH₃ dosing pump, P-292 NH₃ dosing pump, T295 HNO₃ tank, P-291 HNO₃ dosing pump, P-291 HNO₃ dosing pump) feed the required nutrients during the growth phase. As the rate of these dosing pumps is very small, it has not been presented here.
1.6.9. Spent solution treatment section. Following the butanol production phase, the 14.410 m³ of bio-solution is treated in the “spent solution treatment section” (T-550 spent solution tank, P-555 spent solution pump, S-560 clarifier, P-565 sludge pump, T-570 solution to recycle pump, RO-580 reverse osmosis system, P-575 solution to recycle pump). Most of the bio-solution is reused, but some of it is lost and with is some of the chemicals that the solution contains. Note that as this sub-system does not depend on sunlight, it can operate 24 hours a day.
   1.6.9.1. The operations data of the “spent solution treatment section” (T-550, P-555, S-560, P-565 T-570, RO-580, P575) are presented below:

| Description (spent solution treatment section) | Value | Units |
|---|---|---|
| Volume of solution (per cycle) | 14.4 | m³ |
| Clarifying time ( P555, P565, per cycle) | 72 | Hours |
| Spent solution pump P-555 rate | 0.25 | m³/hour |
| Spent solution pump P-555 pressure | 1 | Bar |
| Sludge pump P-565 rate | 14 | liter/hour |
| Reverse osmosis RO-580 feed rate | 100 | liter/hour |
| Reverse osmosis RO-580 brine to feed ratio | 1/7 | |
| Reverse osmosis RO-580 operation time | As needed | |
| Solution to recycle pump P575 rate | 5 | m³/hour |
| Solution to recycle pump P575 pressure | 1.5 | Bar |
| Pump P575 operating time (per cycle) | 3 | Hours |

1.6.9.2. Data of the effluent streams leaving the plant from the mass balance of the “solution treatment section” (T-550, P-555, S-560, P-565 T-570, RO-580, P575) are presented below (it is assumed that 2100 liter bio-solution were passed through the R-580 reverse osmosis unit):

Effluent -spent solution treatment

| Description | H₂O | biomass | C₄H₉OH | K₂CO₃ | Units |
|---|---|---|---|---|---|
| Sludge | 848 | 84.7 | 3.39 | 2.49 | Kg |
| Brine | 300 | 0 | 1.2 | 0.88 | Kg |
| Total (cycle) | 1148 | 84.7 | 4.59 | 3.37 | Kg |

1.6.10. Process water section. The process water needed for the operation of the plant are stored and processed in the “process water section” (T-500 process water tank, T-590 City water tank, P-510 process water pump, P-531 City water pump, E-520 water heat exchanger). Most of the needed process water is recycled bio-solution. The city water source is only used to replace the following losses: water needed for the photosynthesis reactions; water that evaporates and leaves the plant with the oxygen gas produced by photosynthesis; water lost with the sludge and brine streams (see 5.6.8.2). The process water section is equipped with E-520 water heat exchanger to reduce microbial population in the process water as needed. It is assumed that the high pH of the process water (˜9) will by itself limit the growth rate of the microbial population.
   1.6.10.1.The operations data of the “process water section” (T-500, T-590, P-510, P-531, E-520) are presented below.

| Description (process water section) | Value | Units |
|---|---|---|
| Volume of T-500 process water tank | 40 | m³ |
| Process water pump P-510 rate | 5 | m³/hour |
| Process water pump P-510 pressure | 2 | Bar |
| Pump P-510 operation time (per cycle) | 8 | Hour |
| City water pump P531 rate | 2 | m³/hour |
| City water pump P531 pressure | 2 | Bar |
| Pump P-531 operation time (per cycle) | 10 | Hour |
| E-520 operation time | As needed | |

1.6.10.2.The relevant data from the mass balance of the “process water section” (T-500, T-590, P-510, P-531, E-520) is the water consumption per cycle:

| Description (process water section) | Value | Units |
|---|---|---|
| Water consumption (per cycle) | 15.1 | m³ |

1.6.11. CO₂ section. The CO₂ for the plant is absorbed (off-site) from flue gases of installations powered by fossil fuels (thus reducing CO₂ emissions). Therefore, part of the “CO₂ section” is located off-site: (C-010 CO₂ absorber, E-030 heat exchanger). The other part of the “CO₂ section” is located on-site: (P-020 transfer pump, T-110 KHCO₃ storage tank, P-112 KHCO₃ feed pump, C-100 CO₂ generator, E-102 re-boiler, T151 K₂CO₃ storage tank, P120 CO₂ compressor, T-130 CO₂ storage tank). Present here are only two sets of operation parameters: first, per cycle (=31 “days”) data:

| Description (CO₂ section - “per cycle” data) | Value | Units |
|---|---|---|
| KHCO₃ concentration | 17% | wt % |
| KHCO₃ aqueous solution to be trucked in | 311.5 | Ton |
| K₂CO₃ aqueous solution to be trucked out | 302.54 | Ton |
| Trucking distance | ~100 | Mile |

In addition, with regard to hourly operation data:

| Description | Value | Units |
|---|---|---|
| CO₂ generation rate | 24.07 | kg/hour |
| CO₂ compressor P-120 rate | 12.5 | m³/hour |
| CO₂ compressor P-120 pressure | 5 | Bar |

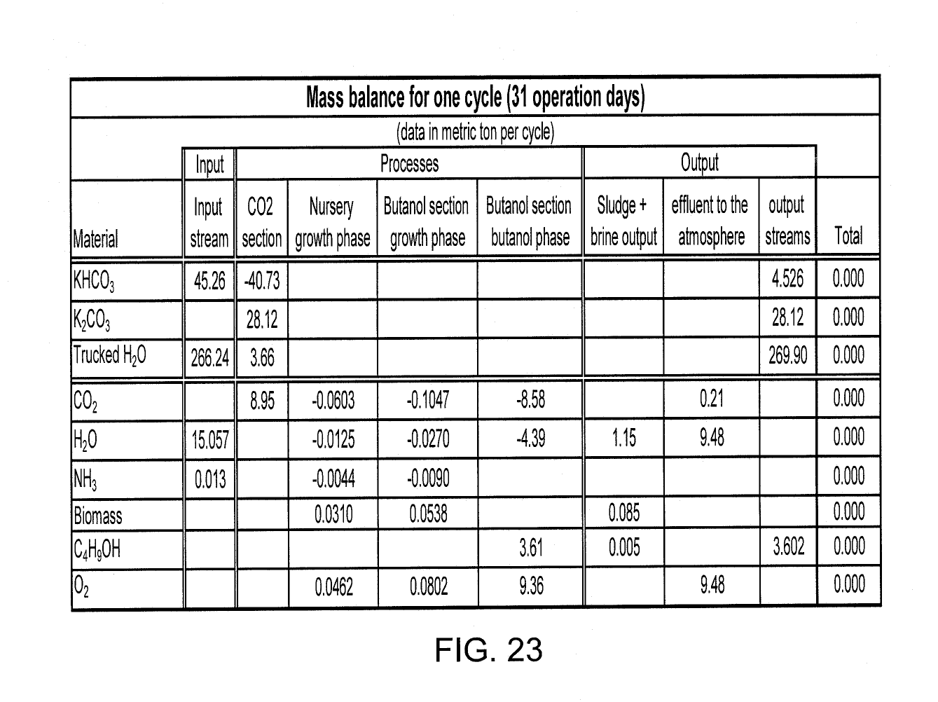

1.7. Mass Balance Summary.
The table in FIG. 23 summarizes the plant's mass balance per a cycle (31 days of operation—see also FIGS. 14A-14B). The table covers only processes where a chemical reaction takes place, therefore the butanol stripping and some other sections are not shown in this table. Also, materials that are used in small amounts are not included.
The first 3 lines deals with getting the CO₂ from flue gases of power plants, trucking potassium bicarbonate aqueous solution to the plant, and trucking potassium carbonate aqueous solution on the way back. (Note that water that is needed for these solutions are presented separately for the water needed for other processes.) The next 6 line summarizes the chemical reactions in the plant. The plant's products and effluents are presented in the 3 columns under “output”.
1.7.1. The first column shows sludge made of the biomass of the dead BPC, the water that flows with it and some brine that is created during the recycling of the bio-solution.
1.7.2. The second column shows the effluents to the atmosphere—mainly oxygen and water vapor. For this calculation we assumed that all the oxygen generated by the photosynthesis will be released to the atmosphere and that an equal amount of water molecules will escape with the oxygen. In addition, we will also lose some CO₂ that may escape the system (about 2%).
1.7.3. The third column shows the main product output stream.

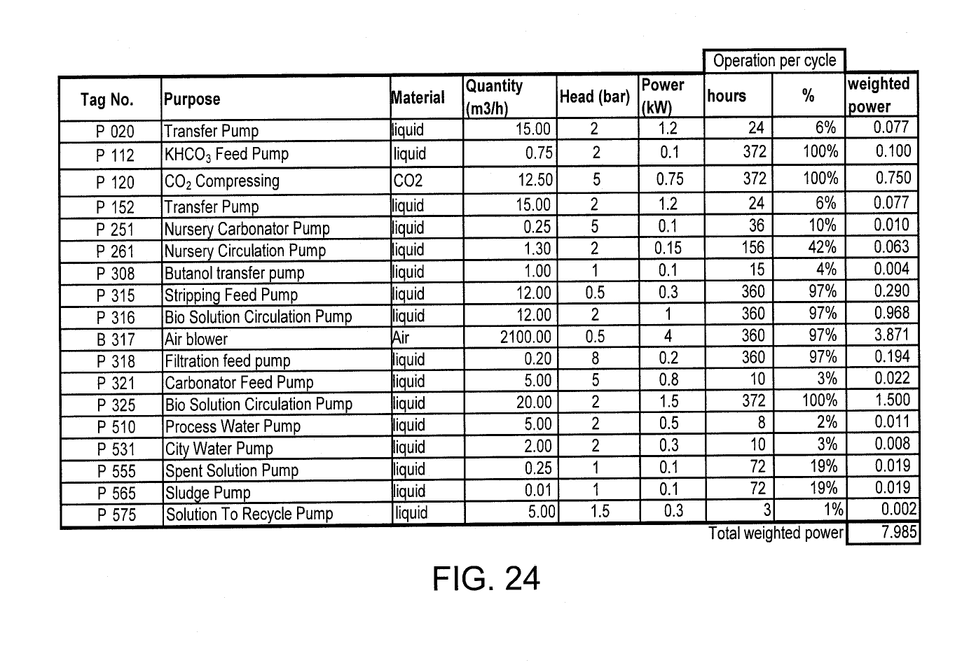

1.8. Energy Requirements
The plant is designed to relay mainly on renewable energy, namely solar power. Besides driving the photosynthesis process, sunlight will drive the following sections of the plant:
1.8.1. Heliostats field. Each heliostat will be powered by a 30×30 cm photovoltaic panel. As the panel will be mounted on the same frame as the heliostat, it will always face the sun. An ultra-capacitor (5 Ah) will provide the necessary back-up power for morning start-up. The control of the heliostat will utilize wireless connections, so that the saving on power and communication cables and installation cost will more than offset the extra cost of the photovoltaic panels.
1.8.2. Heaters and heat pumps. All the heaters and the heat pumps of the plant (including office air-conditioning) will be powered by solar power. A small number of heliostats, (˜10%) will focus direct sunlight on boiler or boilers that will drive all heaters and heat pumps.
The following units will require electric energy: pumps (including blowers and compressors), the offices and the laboratory. The table in FIG. 24 provides the power data of the pumps (very small pumps were not included). The power of each pump is weighted according to the % of its operating time during the cycle. Then, the weighted powers are summed to give the weighted average power consumption of all the pumps in the plant, which is 8 kW. Adding some 2 kW for the combined average power requirements of the offices and laboratory (Air condition not included—see 8.5.2 above) gives the total power requirement of 10 kW.

In one or more of the disclosed embodiments, light that is filtered out by the dichroic mirrors can be used to produce large scale electricity and/or heat using, for example, photovoltaic panels. The produced electricity can be used to supply a portion of or substantially all of the power requirement of the plant. Such a plant must thus be considered to be powered by 100% renewable energy.

The description, embodiments and figures should not to be taken as limiting the scope of the appended claims. Rather, it should be understood that not every disclosed feature is necessary in every implementation of the invention. It should also be understood that throughout this disclosure, where a process or method is shown or described, the steps of the method may be performed in any order or simultaneously, unless it is clear from the context that one step depends on another being performed first. As used throughout this application, the word “may” is used in a permissive sense (i.e., meaning “having the potential to”), rather than the mandatory sense (i.e., meaning “must”).

Certain features of the disclosed subject matter, which are, for clarity, described in the context of separate embodiments, may also be provided in combination in a single embodiment. Conversely, various features of the invention, which are, for brevity, described in the context of a single embodiment, may also be provided separately or in any suitable sub-combination.

It is thus apparent that there is provided, in accordance with the present disclosure, methods and apparatus for extracting energy from insolation. Many alternatives, modifications, and variations are enabled by the present disclosure. While specific embodiments have been shown and described in detail to illustrate the application of the principles of the invention, it will be understood that the invention may be embodied otherwise without departing from such principles. Features of the disclosed embodiments may be combined, rearranged, omitted, etc., within the scope of the invention to produce additional embodiments. Furthermore, certain features may sometimes be used to advantage without a corresponding use of other features. Accordingly, Applicant intends to embrace all such alternatives, modifications, equivalents, and variations that are within the spirit and scope of the present invention.

1. A system for harvesting solar energy, the system comprising:
(a) an elongated upright target, the elongated upright target including first and second vertical surfaces that face away from each other; and
(b) first and second reflection assemblies located on respective sides of the elongated upright target such that the first reflection assembly is located on the first side of the elongated upright target and the second reflection assembly is located on the second side of the elongated upright target,
each reflection assembly including:
(i) a respective field of heliostats located on the respective side of the target, and
(ii) a respective at least partially reflecting element located above the heliostat field.

2. The system of claim 1, the reflection assemblies are configured such that between 10% and 50% of the solar energy impinging upon the heliostats in each field of heliostats is respectively reflected by the respective reflection assembly onto the respective side of the elongated target.

3. The system of claim 1, wherein the target includes a photovoltaic assembly that receives some light from the heliostat which traverses a partially reflective element.

4. The system of claim 1, wherein the target is a bioreactor for generating biofuel.

5. The system of claim 1, wherein the left and right vertical walls of the target include an optically diffusive element for distributing light within the target.

6. The system of claim 1, wherein the incoming light is substantially uniformly distributed within the target.

7. The system of claim 6, wherein the substantially uniform light distribution is uniform in the horizontal direction.

8. The system of claim 6, wherein the substantially uniform light distribution is uniform in the vertical direction.

9. The system of claim 1, wherein at least 10 suns of light are concentrated at each partially reflecting element.

10. The system of claim 1, configured so that at least 50% of the light either traverses said reflecting element in an upward direction and/or is reflected in a downward direction at target.

11. A system for harvesting solar energy comprising:
a target having first and second surfaces, the first surface being non-coplanar with respect to said second surface;
first and second reflecting assemblies, the first reflecting assembly being arranged to reflect incident solar radiation at said first target surface, the second reflecting assembly being arranged to reflect incident solar radiation at said second target surface, wherein
each reflecting assembly includes at least one heliostat and at least one wavelength selective reflector, the at least one heliostat being configured to reflect solar radiation onto the at least one wavelength selective reflector and thereby onto the respective target surface.
